(19) United States
(12) Patent Application Publication
(10) Pub. No.: US 2013/0240744 A1
(43) Pub. Date: Sep. 19, 2013

(54) NEUTRON DETECTION CHIP ASSEMBLY

(71) Applicant: TRUSTED SEMICONDUCTOR SOLUTIONS, INC., Anoka, MN (US)

(72) Inventors: Allan Thomas Hurst, JR., Anoka, MN (US); Danny R. Kagey, Columbia, MN (US); Harold Diederich, Big Lake, MN (US)

(21) Appl. No.: 13/874,977

(22) Filed: May 1, 2013

Related U.S. Application Data
(63) Continuation-in-part of application No. 13/463,529, filed on May 3, 2012.
(60) Provisional application No. 61/640,981, filed on May 1, 2012.
(60) Provisional application No. 61/654,754, filed on Jun. 1, 2012.
(60) Provisional application No. 61/482,037, filed on May 3, 2011.

(51) Int. Cl. G01T 3/08; H01L 31/18

(52) U.S. Cl. CPC G01T 3/08; H01L 31/18
USPC 250/370.05; 438/56

(57) ABSTRACT

A neutron detector and method of manufacture are provided. The neutron detector includes a sensing element structure having a substrate with a front surface and a back surface, opposite to the front surface. A semiconductor sensing element is fabricated in an active semiconductor layer on the front surface of the first substrate and is sensitive to a charged particle. A neutron conversion structure is attached to the back surface and includes neutron conversion material that emits the charged particle in response to a reaction with neutrons.

### CROSS-REFERENCE TO RELATED APPLICATIONS

The present application is based on and claims the benefit of U.S. Provisional Patent Application No. 61/640,981, filed May 1, 2012 and U.S. Provisional Patent Application No. 61/654,754, filed Jun. 1, 2012; and is a continuation-in-part of U.S. application Ser. No. 13/463,529, filed May 3, 2012, which is based on and claims the benefit of U.S. Provisional Patent Application No. 61/482,037, filed May 3, 2011; the contents of which are hereby incorporated by reference in their entireties.

### STATEMENT REGARDING FEDERALLY SPONSORED RESEARCH OR DEVELOPMENT

None.

### THE NAMES OF PARTIES TO A JOINT RESEARCH AGREEMENT

None.

### FIELD OF THE DISCLOSURE

The present disclosure is directed in general to a neutron detection device. A specific example of the present disclosure is directed to a semiconductor device and assembly for detection of neutrons, which utilizes a neutron conversion layer in close proximity to charge-sensitive semiconductor devices. In one particular aspect, the present disclosure relates to a method to manufacture a neutron detection chip assembly.

### BACKGROUND OF THE DISCLOSURE

The detection of radioactive material is of critical importance for applications such as monitoring safety of nuclear power plants and detecting the transport of nuclear materials by unauthorized individuals.

Nuclear materials emit several types of radiation, such as alpha particles, beta particles, gamma rays, and neutrons. Neutrons can be detected from nuclear material that is insulated by a lead shield since neutrons are capable of passing through the lead shield. However, these neutrons can be difficult to detect since neutrons are non-charged particles that may not interact directly with electronic sensing devices.

Silicon-based semiconductor devices have been proposed recently to sense alpha particles emitted from a neutron converter material in response to an n. alpha reaction. The converter material converts incident neutrons into emitted charged particles, which are more readily sensed in a semiconductor diode structure. Such devices therefore serve as neutron detectors. These diode structures, however, can have a high level of internal noise, which can make it difficult to measure low levels of neutrons or to detect single neutron events.

In addition, it has been proposed to use a commercial memory circuit with a neutron converter to detect a Single Event Upset (SEU) particle reaction. Y. As described in Y. Arita et al., “Experimental Investigation of Thermal Neutron-Induced Single Event Upset in Static Random Access Memories,”, Jpn. J. Appl. Phys. 40, pp L151-153 (2001), ¹⁰B in the dopant or borophophosilicate glass (BPSG) passivation layer sensitizes a circuit to neutron radiation. Based on this sensitivity, Houssain U.S. Pat. No. 6,075,261 suggests using a conventional semiconductor memory structure as a neutron detector, wherein a neutron-reactant material (a converter such as boron) is coated over a conventional flash memory device. In this proposal, alpha particles emitted by the boron pass through the structural layers of the circuit before they reach the active semiconductor. This limits the resulting charge in the active semiconductor layer for detecting a single event upset.

August et al. U.S. Pat. No. 7,271,389 and Hughes U.S. Pat. No. 6,867,444 disclose a neutron detection device that utilizes a neutron conversion layer in close proximity to charge-sensitive elements such as conventional memory cells. The device provides the neutron conversion layer in close proximity to the active semiconductor layer of the memory cells. This location increases the sensitivity of the neutron detection device.

### SUMMARY

An illustrative aspect of the present disclosure relates to a neutron detector device comprising a sensing element structure and a neutron conversion structure. The sensing element structure comprises a first substrate with a front surface and a back surface, opposite to the front surface; and a semiconductor sensing element, which is sensitive to a charged particle and is fabricated in an active semiconductor layer on the front surface of the first substrate. The neutron conversion structure is attached to the back surface and comprises neutron conversion material that emits the charged particle in response to a reaction with neutrons.

In one particular embodiment, the neutron conversion structure further comprises a second substrate, distinct from the first substrate, wherein the neutron conversion material is fabricated on the second substrate. The neutron conversion structure is attached to the back surface of the first substrate such that the neutron conversion material is positioned between the second substrate and the first substrate.

In a particular embodiment, the device comprises an assembly of the sensing element structure and the neutron conversion structure, which are distinct structures that are adhered together to form the assembly.

In a particular embodiment, the neutron conversion structure is adhered to the sensing element structure by an adhesive positioned between the neutron conversion material and the back surface of the first substrate.

In a particular embodiment, the first substrate has a thickness and comprises a cavity extending into the back surface at least partially through the thickness. The cavity overlaps a surface area consumed by the semiconductor sensing element along a plane parallel to the front surface. The cavity reduces the thickness of the first substrate between the neutron conversion material and the semiconductor sensing element.

In a particular embodiment, the cavity extends through the entire thickness of the first substrate.

In a particular embodiment, the first substrate comprises a silicon layer; and the cavity comprises a gap fill medium having physical properties that attenuate travel of alpha particles and Lithium ions less than the silicon layer.

In a particular embodiment, the gap fill medium is selected from the group consisting of a vacuum, air, helium, hydrogen, nitrogen and neon.

In a particular embodiment, the sensing element structure comprises: a plurality of semiconductor sensing elements, each being fabricated in the active semiconductor layer on the front surface of the first substrate and sensitive to charged particles generated by the neutron conversion material; and a plurality of cavities extending into the back surface at least partially through the thickness, each of the cavities overlapping a surface area consumed by at least some of the plurality of semiconductor sensing elements along the plane parallel to the front surface.

In a particular embodiment, the neutron conversion structure further comprises a second substrate, distinct from the first substrate. The second substrate comprises a front surface facing the back surface of the first substrate. The front surface of the second substrate comprises a plurality of protrusions or depressions. The neutron conversion material is fabricated on the front surface of the second substrate. The neutron conversion structure is attached to the back surface of the first substrate such that the neutron conversion material is positioned between the front surface of the second substrate and the back surface of the first substrate.

In a particular embodiment, the first substrate has a thickness and the sensing element structure comprises: a plurality of semiconductor sensing elements, each being fabricated in the active semiconductor layer on the front surface of the first substrate and sensitive to charged particles generated by the neutron conversion material; and a plurality of cavities extending into the back surface at least partially through the thickness, each of the cavities overlapping a surface area consumed by at least some of the plurality of semiconductor sensing elements along a plane parallel to the front surface, and each of the cavities being aligned with at least one of the plurality of protrusions or depressions.

In a particular embodiment, the sensing element structure comprises a neutron detector circuit formed in the active semiconductor layer. The circuit comprises: the semiconductor sensing element, which comprises a transistor having a body; a control circuit having a sense mode in which the control circuit is configured to bias the transistor so that the body is electrically-floating and sensitive to the charged particle; and a latch connected to the control circuit and having a logic state that is controlled by the transistor.

A further aspect of the disclosure relates to a method of manufacturing a neutron detector device. The method includes fabricating a sensing element structure comprising: a first substrate with a front surface and a back surface, opposite to the front surface; and an active semiconductor layer on the front surface of the first substrate, which comprises a semiconductor sensing element that is sensitive to a charged particle. The method further includes and fabricating a neutron conversion structure separately from the sensing element structure, the neutron conversion structure comprising neutron conversion material that emits the charged particle in response to a reaction with neutrons; and attaching the neutron conversion structure to the back surface of the first substrate.

In a particular embodiment, the method includes performing a functionality test on at least one of the sensing element structure or the neutron conversion structure subsequent to the steps of fabricating the respective sensing element structure or neutron conversion structure and prior to the step of attaching.

A further aspect of the present disclosure relates to a neutron detector, which includes: a sensing element structure comprising a substrate, a semiconductor sensing element that is fabricated on a front surface of the substrate and is sensitive to a charged particle, and a back surface opposite to the first surface; a neutron conversion structure attached to the back surface, which is configured to generate the charged particle in response to a reaction with a neutron; and a recess formed in the back surface, between the neutron conversion structure and the semiconductor sensing element.

### BRIEF DESCRIPTION OF THE DRAWINGS

FIG. 1 is a simplified cross-sectional view, which schematically illustrates a neutron detection assembly and the basic operation of a neutron detection event according to an exemplary embodiment of the present disclosure.

FIGS. 2A and 2B are diagrams of PMOS and NMOS transistors with associated parasitic bipolar transistors.

FIG. 2C illustrates a cross-sectional view of a PMOS transistor and its parasitic bipolar transistor.

FIG. 3 is a block diagram illustrating a neutron detection circuit according to an illustrative aspect of the disclosure.

FIG. 4 is a schematic diagram of an SRAM circuit.

FIG. 5 is a schematic diagram of a sensing element array and latch.

FIG. 6A illustrates a schematic diagram of a sensing PMOS device with an extended charge collection plate, according to an example of the present disclosure.

FIG. 6B illustrates a physical layout diagram of the sensing PMOS device with an extended charge collection plate, according to an example of the present disclosure.

FIG. 7 illustrates a cross-sectional view of a sensing element structure at an intermediate step in the fabrication process, prior to etching windows on the back side of the structure substrate.

FIG. 8 illustrates a cross-sectional view of sensing element structure at a subsequent processing step in which one or more windows are etched or otherwise formed into the substrate.

FIG. 9A illustrates a cross-sectional view of a neutron conversion structure prior to assembly with a sensing element structure, shown in FIG. 8.

FIG. 9B illustrates a cross sectional view of a neutron conversion structure according to an alternative embodiment in which a surface of a base layer is formed with rectangular depressions.

FIG. 9C illustrates a cross sectional view of a neutron conversion structure according to an alternative embodiment in which a surface of the base layer is formed with V-shaped depressions.

FIG. 9D illustrates a cross sectional view of a neutron conversion structure according to an alternative embodiment in which a surface of the base layer is formed with parabolic protrusions.

FIG. 9E illustrates a cross sectional view of a neutron conversion structure according to an alternative embodiment in which a surface of the base layer is formed with parabolic depressions.

FIG. 10A illustrates a cross sectional view of an assembled neutron detector, according to an exemplary embodiment of the disclosure.

FIG. 10B illustrates a cross sectional view of an assembled neutron detector, according to an embodiment in which the base layer of the neutron conversion structure has a surface with V-shaped trenches.

FIG. 10C illustrates a cross sectional view of an assembled neutron detector, according to an embodiment in which the base layer of the neutron conversion structure has a surface with parabolic-shaped trenches.

FIG. 10D illustrates a cross sectional view of an assembled neutron detector according to another embodiment in which the thickness of the sensing element substrate is reduced.

FIG. 10E illustrates a cross sectional view of an assembled neutron detector according to another embodiment in which the neutron conversion structure is sized to fit within a window or cavity formed in the sensing element structure.

FIG. 11 is a graph illustrating alpha particle and Lithium ion range of travel in silicon when a thermal neutron is captured by Boron-10.

FIG. 12 is a graph that illustrates a Bragg curve, which shows the range of an alpha particle in a low-density media such as air.

FIG. 13 is a graph that illustrates the mean free path of an alpha particle of various energy levels.

FIG. 14 is a flow diagram, which illustrates the basic steps for creating a neutron detector assembly utilizing two independent structures, according to an exemplary embodiment of the present disclosure.

FIG. 15 is a flow diagram, which illustrates the basic steps for creating a neutron detector assembly at the wafer level, according to an exemplary embodiment of the present disclosure.

FIG. 16 is a flow diagram, which illustrates the basic steps for creating a neutron detector assembly at the die level, according to an exemplary embodiment of the present disclosure.

FIG. 17 is a diagram illustrating a stack of multiple, interconnected neutron detector chips, according to an embodiment of the disclosure.

FIG. 18 is a diagram illustrating a sample architecture layout of circuit elements that are formed within the active semiconductor layer of the sensing element structure, according to an exemplary embodiment of the present disclosure.

### DETAILED DESCRIPTION OF ILLUSTRATIVE EMBODIMENTS

The following is provided as a description of examples of one or more aspects of the present disclosure. The below detailed description and above-referenced figures should not to be read as limiting or narrowing the scope of the invention as will be claimed in issued claims. It will be appreciated that other embodiments of the invention covered by one or more of the claims may have structure and function which are different in one or more aspects from the figures and examples discussed herein, and may embody different structures, methods and/or combinations thereof of making or using the invention as claimed in the claims, for example.

Also, the following description is divided into sections with one or more section headings. These sections and headings are provided for ease of reading only and, for example, do not limit one or more aspects of the disclosure discussed in a particular section and/or section heading with respect to a particular example and/or embodiment from being combined with, applied to, and/or utilized in another particular example, and/or embodiment which is described in another section and/or section heading. Elements, features and other aspects of one or more examples may be combined and/or interchangeable with elements, features and other aspects of one or more other examples described herein.

Embodiments of the present disclosure can be used in a variety of different applications of neutron detectors and housed in a variety of different types of apparatus.

Further, various elements and drawings may not be drawn to scale and are provided for illustrative purposes only. For example, the respective thickness of various layers of a semiconductor or neutron detector device are not drawn to scale.

### 1. Introduction

An exemplary aspect of the present disclosure relates to a neutron chip detection assembly and a method of manufacturing such an assembly in which the structure for converting a neutron into an alpha particle or Lithium ion, for example, is manufactured separately from the structure for detecting the resulting alpha particle or Lithium ion. This permits manufacture of the separate structures to be optimized independently. The two structures can then be joined to form a neutron detection chip assembly.

Traditionally, silicon-based semiconductor devices are fabricated by creating a neutron conversion layer on top of the semiconductor device that detects the resulting alpha particles or Lithium ions. Materials, such as boron are deposited on the silicon to sensitize the circuit to neutron radiation. This is not a trivial, high-yielding process. Efforts to date have resulted in sensors with poor detection efficiency. Also, Boron is a “P” dopant. Depending on the particular methodology, subsequent processing after Boron is in the presence of silicon, which increases the temperature of the materials, may inadvertently make the silicon p-type. This may adversely affect functionality.

Traditional processing typically includes silicon etching, followed by deposition of neutron conversion material onto the sensor device. This serial process is performed so that the neutron conversion material can be placed in close proximity to the active device thereby improving the likelihood that alpha particles or Lithium ions will reach the active semiconductor device for detection. This process is proven, but it is not ideal for high volume manufacturing. This process is typically performed at the die level where each device is serially etched and then deposited with the neutron conversion material. This is a time consuming, high cost, low yield process. Attempting this processing at the wafer level is technically challenging and unproven. While a silicon etch performed at the wafer level may be possible, it may leave the die so fragile that it may be difficult or virtually impossible to complete the deposition and the assembly steps necessary to complete the manufacture of the neutron sensor.

The inventors of the present disclosure believe one factor in the poor detection efficiency of traditional processing is that the boron conversion material is not located close enough to the active semiconductor layer. Thus the alpha particles or Lithium ions generated by the boron conversion material dissipate their energy in the intervening material (such as the various interconnect and insulating layers) and cannot generate a sufficient charge in the active semiconductor layer to be detected.

The present disclosure describes a method of manufacture for silicon-based semiconductor neutron sensors that improves the manufacturing process and improves the likelihood that a neutron “hit” will be detected by sensors formed on the active semiconductor layer. This method also takes advantage of the economics of large-scale semiconductor manufacturing, where many steps can be formed at the wafer or die level, for example.

For example, the method of manufacture includes: 1) fabricating a sensing element wafer or die to create a sensing element structure; 2) fabricating a neutron conversion structure as a wafer or die; and 3) assembling the sensing element structure with the neutron conversion structure to form a neutron detection chip assembly. An exemplary goal is to create a manufacturing process that is low cost, high yield, and improves the sensitivity of the neutron detector.

Thus in an exemplary embodiment, the manufacturing process is separated into two independent steps: fabrication of the sensing element structure and fabrication of the neutron conversion structure. The sensing element structure can be fabricated either at the wafer or die level, so that at completion, silicon has been etched away only from the active area of the sensing element, for example. The neutron conversion structure is fabricated, for example, by depositing a neutron conversion material on a base substrate so that a stand-alone neutron conversion structure can be fabricated as a separate and distinct structure from the sensing element structure. Once both structures are fabricated, they are then joined together to create a neutron detection chip assembly. In an exemplary embodiment, this process removes yield dependencies of performing the manufacturing process serially and supports high volume manufacturing.

### 2. Example Embodiment of a Neutron Sense Element

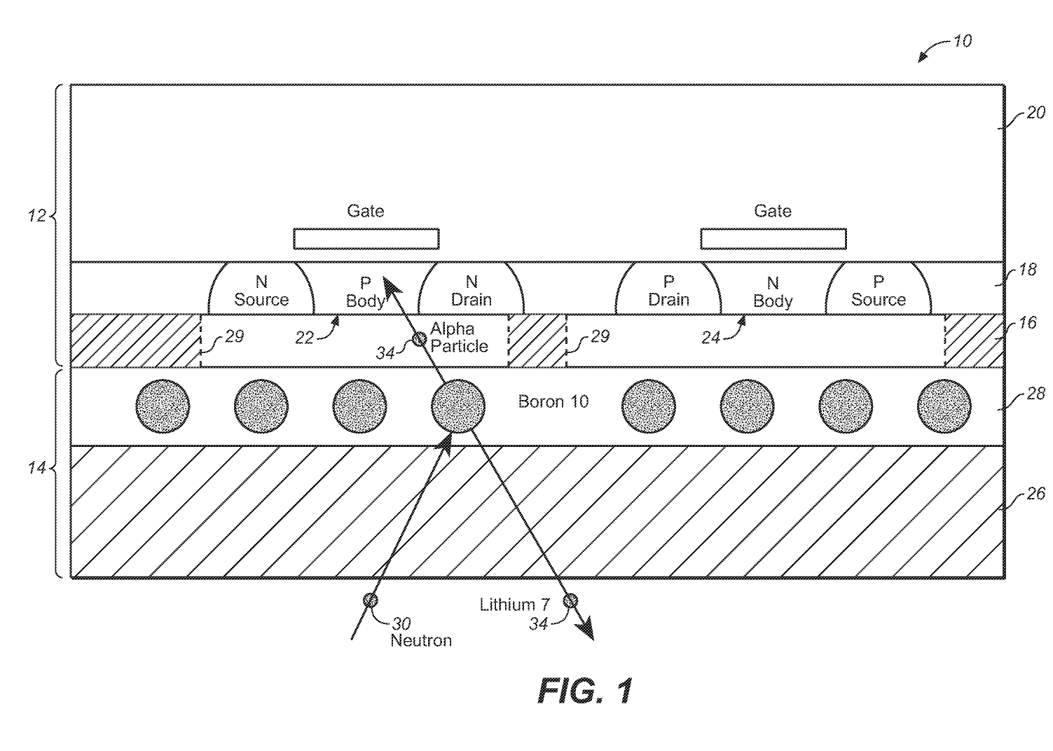

FIG. 1 is a simplified cross-sectional view, which schematically illustrates a neutron detection assembly 10 and the basic operation of a neutron detection event according to an exemplary embodiment of the present disclosure. As explained in further detail below, neutron detection assembly 10 is formed of a sensing element structure 12 and a neutron conversion structure 14, which are separately fabricated and then joined together to form assembly 10. The details of the structures 12 and 14 are simplified in FIG. 1 to illustrate the basic operation of a neutron detection event.

Sensing element structure 12 includes a substrate 16, such as a silicon-on-insulator (SOI) substrate, and active semiconductor layer 18 and an interconnect layer 20. Active silicon layer 18 includes one or more metal oxide semiconductor (MOS) transistors 22 and 24. The semiconductor elements of transistors 22 and 24 are fabricated within active semiconductor layer 18. Interconnect layer 20 includes various individual layers and elements that electrically interconnect the semiconductor devices in a pattern to form a desired circuit configuration. These interconnect elements can include, for example, polysilicon interconnects, metal layers, vias between layers, insulating layers, etc.

Neutron conversion structure 14 includes a base layer or substrate 26 and a neutron conversion layer 28 and is attached to the substrate 16 of sensing element structure 12, with neutron conversion layer 28 being positioned in close proximity to the MOS transistors in active semiconductor layer 18. Neutron conversion layer 28 includes a neutron conversion material comprising any suitable material that emits charged particles in response to a reaction with neutrons. For example, the neutron conversion layer can include materials such as but not limited to Boron, Lithium or a combination of Boron and Lithium. In specific examples, the material includes Boron-10 or Lithium-6. As explained further below, one or more windows 29 may be etched or otherwise formed in substrate 16, which contain a medium such as a vacuum, air or other low-density gas with a low stopping power for charged particles.

Neutron conversion structure 14 can be located in a variety of different locations on or between various layers of sensing element structure 12. In this example, neutron conversion structure 14 is located below the active semiconductor layer 18, such as below a silicon dioxide insulating layer that is adjacent active semiconductor device layer 18 in a silicon-on-insulator example of an integrated circuit chip. In another example, the neutron conversion structure 14 is attached on top of one or more of the interconnect layers 20. For example, the neutron conversion structure may be fabricated on top of (or in replace of) a passivation layer. Various insulating layers and/or barrier layers can also be used relative to conversion layer 28 and the other layers of assembly 10.

Since a neutron has no electrical charge, the presence of the neutron cannot be sensed directly by an electronic circuit. However, a neutron does have a nuclear interaction with certain elements, such as a Boron10 atom in which two charged particles are created. An interaction between a neutron and a Boron10 atom creates an alpha particle and a Lithium ion with Linear Energy Transfer (LET) values of, for example, 1.47 and 0.84 (MeV-cm²/mg) respectively. As shown in FIG. 1, as a neutron 30 transits assembly 10, the nuclear interaction between the neutron and conversion layer 28 creates an alpha particle 32 and a Lithium ion 34. If one of these particles passes through a charge-sensitive device in sensing element structure 12, such as a biased semiconductor junction, the energy of such a charged particle can create a charge in the junction due to hole-electron pair generation, for example. This charge can then be detected by circuitry coupled to the semiconductor junction. In the example shown in FIG. 1, alpha particle 32 passes through the body of transistor 22, which is sensitive to the charge carried by alpha particle 32 and Lithium ion 34.

Examples of suitable charge-sensitive elements include but are not limited to biased semiconductor junctions, such as P-type or N-type MOS transistors formed on a silicon-on-insulator (SOI) substrate. Other charge-sensitive elements and devices can also be used, such as other semiconductor materials. The neutron conversion material can include any material that emits charged particles in response to a reaction with neutrons, such as material based on Boron and/or Lithium. In the case of Boron, these charged particles can include alpha particles and Lithium ions, for example. In the case of Lithium, these charged particles can include tritons, for example. Examples of other neutron conversion materials include proton emitters and electron emitters.

As described below with reference to a particular embodiment, a plurality of these neutron sense elements (i.e., biased semiconductor junctions) is arranged in an array, which generates a signal (e.g., a voltage change) that can be captured by a latch circuit. The latch circuit has a critical charge, Qcrit, which is the amount of charge generated in the sense element to provide a sufficient signal to change the state of the latch.

The charge that can be deposited in a semiconductor junction is determined by the LET of the ion, the material density, and the junction dimensions. Based on the minimum Qcrit of the Lithium ion, a sense element can be designed that converts the Qcrit into a digital signal level. Since the LET of the alpha particle is higher, it will also be captured, which increases efficiency by detecting both alpha particles and Lithium ions. The design and optimization of the sense element may be performed in conjunction with the design of the latch, since the latch has to change state upon the sense element signal.

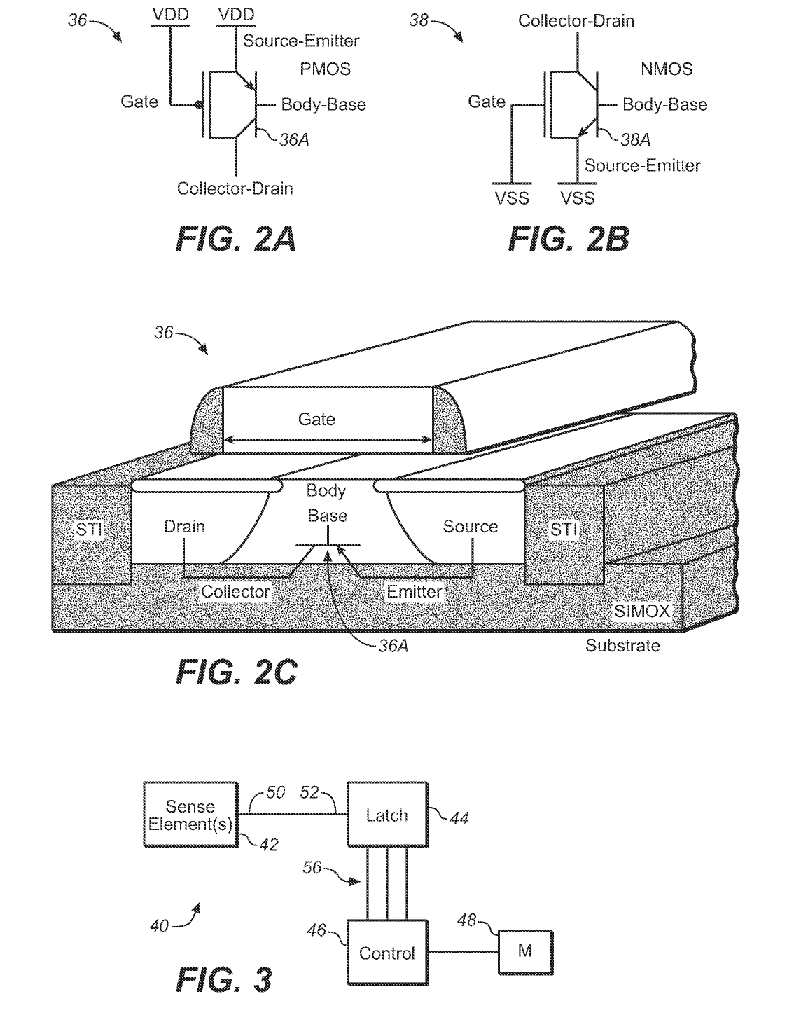

The specific ion sense mechanism is now described for the example of a PMOS transistor 36, shown in FIG. 2A, and an NMOS transistor 38, shown in FIG. 2B. A MOS transistor has four nodes: a source, a gate, a drain and a body. The gate forms a current-control terminal, which controls current flow between the source and drain. MOS transistors 36 and 38 also form parasitic bipolar transistors 36A and 38A, respectively, in which the electrically-floating body forms a parasitic, current-control terminal referred to as a base, and the source and drain form an emitter and a collector of the parasitic bipolar transistor. In normal semiconductor logic operation these parasitic bipolar devices 36A and 38A are reverse-biased such that their negative effects are minimized. FIG. 2C illustrates a cross-sectional view of PMOS transistor 36 and its parasitic bipolar device 36A.

During normal MOS operation when the gate voltage is in the “on” state, transistors 36 and 38 become conductive and have low resistance between source and drain, which permits current to flow between the source and drain. When the gate voltage in the “off” state, the source to drain resistance is high, which prevents current from flowing between the source and drain.

The parasitic bipolar transistor, 36A or 38A, is not active during normal circuit operation. However if a large enough charge is deposited by an alpha particle or a Lithium ion into the floating body region of an “off” MOS transistor, the charge can turn the parasitic bipolar transistor “on” into a conductive state. The resulting current that flows between the source and drain, which in this case is from the parasitic bipolar transistor in the MOS structure, can be used to change the state of a latch circuit.

Referring to FIG. 2A, PMOS transistor 36 can be configured as a neutron sense element by connecting the source-emitter to a positive power supply terminal VDD and connecting the gate to either the positive power supply terminal VDD or a power supply having a higher voltage than VDD. The drain can be connected to the latch input to provide a sense signal to change the state of the latch. An ion hit to the floating body-base region of PMOS transistor 36 may cause the base-emitter junction to forward bias and turn “on” the parasitic pnp transistor, thus providing the sense signal to the latch.

Referring to FIG. 2B, NMOS transistor 38 can be configured as a neutron sense element by connecting the source-emitter to a ground voltage and connecting the gate to either the ground supply terminal VSS or a voltage terminal that is lower (or more negative) than VSS. The drain can be connected to the latch input to provide a sense signal to change the state of the latch. An ion hit to the floating body-base region of NMOS transistor 38 may cause the base-emitter junction to forward bias and turn “on” the parasitic npn transistor, thus providing the sense signal to the latch.

Circuit models of the bipolar operation have been imbedded into basic MOS transistor models that are used by designers for circuit emulation. These models incorporate the physical dimensions such as oxide thickness, gate width, and gate length. Electrical characteristics such body resistance, gate leakage, junction leakage, sub-threshold leakage, junction capacitance, and gate capacitance are also included.

Along with the circuit models, a set of transient “hit models” that emulate the charge deposition in the bipolar base region can be used to predict electrical performance of a biased semiconductor junction as an ion sense element. Detailed circuit design of the sense element can involve a matrix of simulations that vary transistor sizes, charge deposition, temperature, voltage, transistor thresholds and circuit configurations, for example. The particular design of a sense element should provide a detectable signal to a latch (or other detection circuit) after an alpha particle hit or a Lithium ion hit.

### 3. Neutron Sense Latch

FIG. 3 is a block diagram illustrating a neutron detection circuit 40 according to an illustrative aspect of the disclosure. Neutron detection circuit 10 includes a charged particle sensor 42, a detection latch 44 and a control circuit 46. Charged particle sensor 42 and latch 44 are fabricated on a semiconductor integrated circuit die to form the sensing element structure 12 shown in FIG. 1, and all or part of control circuit 46 can be fabricated on the same die as charged particle sensor 42 and latch 44 or on a separate die or circuit, for example.

In a particular example, charged particle sensor 42 includes one or more biased semiconductor junctions, which are configured to detect charged particles emitted by a neutron conversion material, such as in the manner discussed with reference to FIGS. 1 and 2. Charged particle sensor 42 may also include one or more electrically-floating, extended area charge collection plates that are electrically-connected to the floating body of the one or more biased semiconductor junctions. The biased semiconductor junctions provide a signal on sense output 50 indicative of a “hit” by a charged particle created by neutron conversion structure 14 (shown in FIG. 1). Sense output 50 is electrically coupled to latch input 52. Upon detection of a charged particle, one or more of the sense elements in sensor 42 deposits a charge onto (or removes a charge from) sense output 50, which changes the state of latch 44. The resulting change in the logic state can then be read by control circuit 46.

As discussed in more detail below, control circuit 46 provides a set of control signals 56 to latch 44, which control the operating modes of latch 44 and permit the state of the latch to be read. For example, control circuit 46 supplies control and voltage bias inputs to operate latch 44 in a “set” mode, a “sense” mode and a “read” mode. In the set mode, control circuit 46 sets latch 44 to an initial state. In the sense mode, control circuit 46 biases transistors in latch 44 such that charge deposited onto latch input 52 (or charge removed from latch input 52) by sense elements 42 will change the state of the latch from the “set” state to a “reset” state. The “set” and “reset” states can correspond to suitable logic levels, such as high and low, or low and high, respectively, depending on the circuit configuration. In addition, various transistors in latch 44, itself may be biased to detect the charged particles and upset the state of latch 44. In the “read” mode, control circuit biases transistors in latch 44 to read the state of the latch.

Latch 44 can include any type of memory element in any suitable technology. For example, latch 44 may include a memory element similar to a static random access memory (SRAM) element, a dynamic random access memory (DRAM) element, other types of random access memory elements, non-random access memory elements, charge coupled devices, charge injection devices, or other memory device structures. A particular alternate example is described with reference to below.

In a further embodiment, sense elements(s) 42 are implemented as part of one or more “off” transistors within latch 44.

Neutron detection circuit 40 can further include a plurality of charged particle sensors 42 and respective latches 44, which are controlled by control circuit 46. Control circuit 46 can be configured to each read latch 44, log the results of the read, and re-set the latch at any desired frequency or pattern. For example, control circuit 46 may include an address generator, which automatically, or under processor control, generates a set of addresses that sequentially reads the states of the various latches 44, triggers an upset counter for each latch state reversal, and then re-sets the latch. The upset counter can be configured to count the number of detected “hits” over a predetermined time period and provide the count as an output to a monitor program or device.

Control circuit 46 can be implemented in hardware, software or a combination of both hardware and software. In one example, at least a portion or all of control circuit 46 is implemented as hardware in an integrated circuit. In another example, control circuit 46 includes a processor and a computer-implemented program stored on memory 48. The computer program includes instructions which when executed by the processor, configure the processor to perform the steps of the control function described herein. The instructions may be stored in or transmitted by computer-readable data medium 48. The medium may be a non-transitory hardware storage medium that may be removable or non-removable, such as a compact disk read only memory (CD-ROM), a magnetic floppy disk, a hard disk, on-chip or off-chip random access memory. The medium may also comprise a transmission medium such as an electrical, optical, or radio signal, or a telecommunications network.

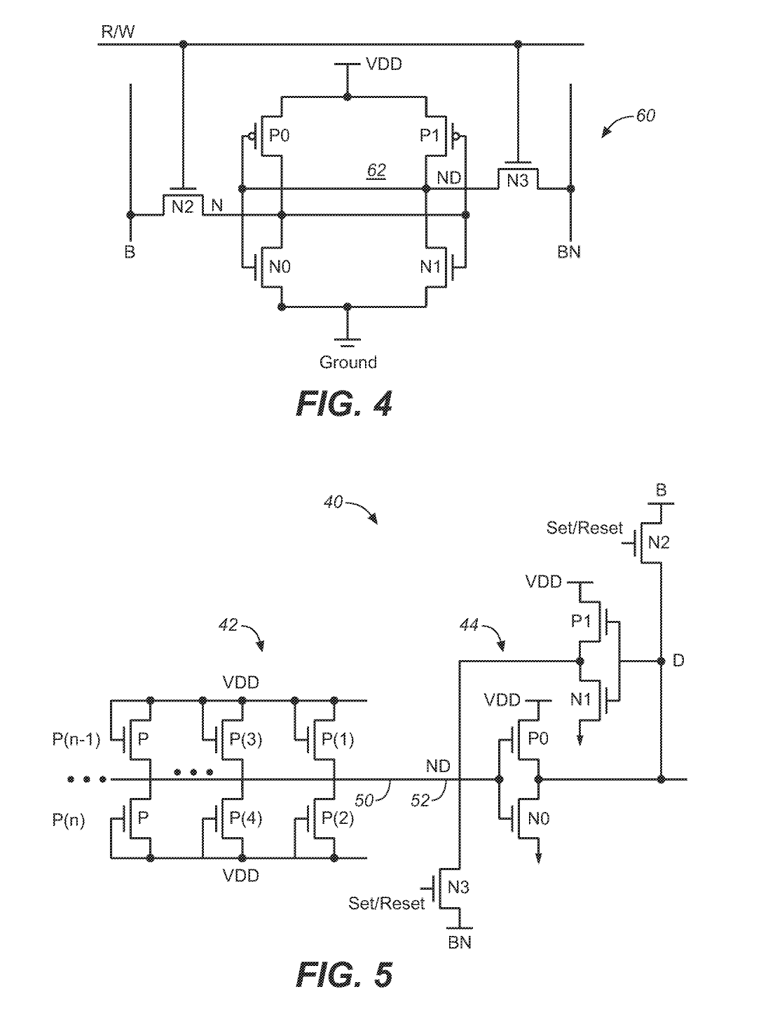

FIG. 4 is a schematic diagram illustrating a typical 6-transistor static random-access memory (SRAM) circuit 60, which can be used for the latch 44 in FIG. 3 and can be coupled to sense elements 42 and/or modified to include a sense element having an extended-area charge detection plate either as a separate element connected to drive the SRAM state or as part of one or more of the “off” transistors within the SRAM itself. Circuit 60 is fabricated on an integrated circuit in a manner such as that described with reference to FIG. 1, for example, such that neutron conversion material is positioned in close proximity to one or more (for example all) of the biased semiconductor junctions.

In this example, memory cell 60 includes two cross-coupled inverters formed by transistors P0/N0 and P1/N1. Each of the transistors includes first and second terminals and a third terminal, which controls current flow between the first and second terminals. In the case of a P-channel MOS transistor, the first and second terminals are referred to as a source and a drain, and the third terminal is referred to as a gate. Node ND (latch input 52) is coupled to the input of inverter pair P0/N0 and to the output of inverter pair P1/N1. Node D is coupled to the output of inverter pair P0/N0 and to the input of inverter pair P1/N1. N-type pass gate N2 has a drain coupled to a bit line B, a source coupled to output node D, and a gate coupled to read/write control input R/W. N-type pass gate N3 has a drain coupled to latch input node ND, a source coupled to bit line BN, and a gate coupled to control input R/W.

During a “set” mode, control circuit 46 (shown in FIG. 3) places memory circuit 60 in a “set” state in which node D has a logic HIGH (i.e., “1”) state, and node ND has a logic LOW (i.e., “0”) state. To place a “1” in memory circuit 60, which corresponds to a high voltage level VDD on node D, control circuit 46 applies a high voltage to bit line B and a low voltage to bit line BN. Control circuit 46 then applies a logic high voltage to the pass gate control input R/W, which turns on transistors N2 and N3. This pulls node D high to VDD and pulls node ND low to a ground or zero voltage. The zero voltage on ND in turn forces the output of inverter pair P0/N0 on node D to be a high voltage, reinforcing the high voltage passed through N2. With a high voltage on node D, inverter pair P1/N1 reinforces the low voltage on node ND. Control circuit 46 then returns the pass gate control input R/W an inactive, low state, turning off pass gate transistors N2 and N3.

To read the state of memory circuit or cell 60, control circuit 46 precharges bit lines B and BN to a logic high voltage, such as VDD, and applies a logic high voltage to pass gate control input R/W. The bit lines B and BN, which are precharged high, are now left floating. With a “1” state in circuit 60, the low voltage on node ND will slowly start to pull the voltage on bit line BN towards ground. Bit line B line will be pulled high by node D. A differential sense amplifier, not shown in FIG. 4, is used to sense a small voltage difference between bit lines B and BN. This improves the read speed. However, control circuit 46 can read the latch state in a variety of different ways, such as by sensing the state of a either one of bit lines B or BN with a single-ended amplifier or by reading node(s) D or ND directly, for example.

During a “sense” mode, cell 60 waits for detection of an ion hit. After setting cell 60 to a “high” state in the “set” mode, control circuit 46 places cell 60 in the sense mode by holding the pass gate control input R/W low (turning off transistors N2 and N3) and holding bit lines B and BN high. In effect, this also precharges B and BN for a subsequent read. Since node ND is low and node D is high, transistors P1 and N0 reverse-biased in the “off” state and therefore sensitive to a charged particle hit. Also, the

As mentioned above with respect to FIG. 1, neutron conversion material is positioned in close proximity to at least one of the charge-sensitive elements in memory cell 60 of FIG. 4 and/or in a separate sense element 42, shown in FIG. 3. The neutron conversion material emits charged particles, such as alpha particles or Lithium ions, in response to a reaction of the material with a neutron. Referring to FIG. 4, these charged particles may be detected by the charge-sensitive devices P1 or N0 when these devices are reverse-biased in the “off” state. As explained with reference to FIGS. 2A-2C, each of the PMOS and NMOS transistors in cell 60 also forms a parasitic bipolar transistor that is inactive during normal operation. If a large enough charge is deposited on the body region of the “off” transistor, caused by one or more of the emitted charged particles passing through the body region, this charge can turn “on” the parasitic bipolar transistor of a MOS transistor that is biased in the “off” state.

When one or more of the parasitic bipolar transistors in cell 60 turns on, this permits current to flow from voltage bias node VDD to cell node ND. The resulting current can deposit enough charge on latch node ND to change the state of cell 60. When forward biased, these parasitic bipolar devices can deposit a sufficient charge onto latch nodes ND and D or remove a sufficient charge from these nodes to override the state of the “on” MOS transistor in inverter pair P0/N0 or P1/N1, which can force the inverters to change states.

For example, assume a “1” is in the latch, node D is high and node ND is low. In this case, P0 is “on”, N0 is “off”, P1 is “off”, N1 is “on”, and N2 and N3 are “off”. A large ion hit on N0 would briefly turn on N0 and pull node D low. The low voltage on node D causes inverter P1/N1 to drive node ND to a high, thereby changing the state of the latch. Similarly, a large ion hit on P1 would briefly turn on P1, pulling node ND high, causing inverter P0/N0 to drive node D low, thereby changing the state of the inverter. A large ion hit on transistor N3 would turn on transistor N3, pulling node ND high and causing inverter P0/N0 to drive node D low to change the state of the latch. A hit on P0 would cause no upset since the drain and source of P0 are both at a high voltage of VDD, and P0 is already in an on state. A hit on N1 would cause no upset since the drain and source of N1 are both at a low voltage of GND and N1 is already in an on state. Also a hit on N2 would cause no upset since the drain and source of N2 are both at a high voltage of VDD.

The operation of the circuit shown in FIG. 4 thus illustrates an example of a method of detecting a neutron, according to an exemplary embodiment of the present disclosure. In a specific exemplary embodiment, detection may be improved by increasing the physical area of the charge detection elements

As described above, a neutron conversion material emits charged particles in response to a reaction of the neutron conversion material to a neutron. A latch (such as an SRAM memory cell 60 as shown in FIG. 4) is initialized to a first state, and one or more semiconductor sense elements are biased in an OFF state (either within the memory cell or as separate components). The semiconductor sense elements are configured to produce a sense current in response to the charged particles. The sense current changes the state of the latch from the first state to a second, different state. The present state of the latch is then read to detect the change from the first state to the second state.

FIG. 5 is a schematic diagram illustrating in more detail an example of a neutron detector circuit 40 as shown in FIG. 3, according to a particular example in which the charge-sensitive area is increased by utilizing an array of sensing elements that are coupled to an input of the latch. Circuit 40 includes charged particle sensor 42 (comprising an array of elements such as biased semiconductor junctions) and detection latches 44. Circuit 40 can be fabricated on an integrated circuit in a manner such as that described with reference to FIG. 1, for example, such that neutron conversion material is positioned in close proximity to one or more (for example all) of the biased semiconductor junctions contained in sensor 42 and detection latch 44. For example, an area consumed by the conversion material at least partially overlaps at least one of: the area consumed by the plurality of semiconductor sense elements in sensor 42; or the area consumed by the latch.

Similar to an SRAM memory cell, detection latch 44 includes two cross-coupled inverters formed by transistors P0/N0 and P1/N1. Node ND (latch input 52) is coupled to the input of inverter pair P0/N0 and to the output of inverter pair P1/N1. Node D (latch output 54) is coupled to the output of inverter pair P0/N0 and to the input of inverter pair P1/N1. N-type pass gate N2 has a drain coupled to a bit line B (which is used as a voltage bias input), a source coupled to output node D, and a gate coupled to control input SET/RESET. N-type pass gate N3 has a drain coupled to latch input node ND, a source coupled to bit line BN, and a gate coupled to control input SET/RESET.

Sensing elements 42 can include a plurality of P-type transistors labeled P(1) . . . P(n) coupled together in parallel, where “n” is a positive integer values greater than or equal to 1. In particular examples, “n” can be any integer greater than or equal to 2, less than or equal to infinity, less than or equal to 10 and/or less than or equal to 100, for example. The plurality of transistors P(1) to P(n) are coupled together in parallel and reverse-biased in an “off” state. Each of the transistors includes first and second terminals and a third, which controls current flow between the first and second terminals. In the case of a P-channel MOS transistor, the first and second terminals are referred to as a source and a drain, and the third terminal is referred to as a gate. In the example shown in FIG. 4, each of the transistors P(1) to P(n) has its gate and source coupled to a relatively positive power supply voltage bias node VDD and its drain coupled to sense output 50. In an alternative example, each gate is coupled to a voltage bias terminal having a voltage that is greater than VDD. Each of the transistors P(1) to P(n) is therefore biased in an “off” state, which blocks current from flowing from VDD to sense output 50. In another embodiment, detection circuit 40 can include a plurality of N-type transistors labeled N(1) . . . N(n) coupled together in parallel and reverse-biased in an “off” state. Each of the transistors N(1) to N(n) has its gate and source coupled to a relatively negative power supply voltage bias node VSS and its drain coupled to node D (which forms sense output 50 in this example). In an alternative example, each gate is coupled to a voltage bias terminal having a voltage that is less than VSS.

Referring to the embodiment shown in FIG. 5, during the “set” mode, control circuit 46 (shown in FIG. 3) places latch 44 in a “set” state in which node D has a logic HIGH (i.e., “1”) state, and node ND has a logic LOW (i.e., “0”) state. To place a “1” latch 44, which corresponds to a high voltage level VDD on node D, control circuit 46 applies a high voltage to bit line B and a low voltage to bit line BN. Control circuit 46 then applies a logic high voltage to the pass gate control input SET/RESET, which turns on transistors N2 and N3. This pulls node D high to VDD and pulls node ND low to a ground or zero voltage. The zero voltage on ND in turn forces the output of inverter pair P0/N0 on node D to be a high voltage, reinforcing the high voltage passed through N2. With a high voltage on node D2, inverter pair P1/N1 reinforces the low voltage on node ND. Control circuit 46 then returns the pass gate control input SET/RESET an inactive, low state, turning off pass gate transistors N2 and N3.

To read the state of latch 44, control circuit 46 precharges bit line B and BN to a logic high voltage, such as VDD, and applies a logic high voltage to pass gate control input SET/RESET. The bit lines B and BN, which are precharged high, are now left floating. With a “1” state in latch 44, the low voltage on node ND will slowly start to pull the voltage on bit line BN towards ground. Bit line B line will be pulled high by node D. A differential sense amplifier, not shown in FIG. 5, is used to sense a small voltage difference between bit lines B and BN. This improves the read speed. However, control circuit 46 can read the latch state in a variety of different ways, such as by sensing the state of a either one of bit lines B or BN with a single-ended amplifier or by reading node(s) D or ND directly, for example.

During the “sense” mode, latch 44 waits for detection of an ion hit. After setting latch 44 to a “high” state in the “set” mode, control circuit 46 places latch 44 in the sense mode by holding the pass gate control input SET/RESET low (turning off transistors N2 and N3) and holding bit lines B and BN high. In effect, this also precharges B and BN for a subsequent read.

As mentioned above, neutron detection circuit 40 includes a neutron conversion material, such as that shown in FIG. 1, positioned in close proximity to at least one of the charge-sensitive elements in sensor 42 or the latch 44. The neutron conversion material emits charged particles, such as alpha particles or Lithium ions, in response to a reaction of the material with a neutron. These charged particles may be detected by the charge-sensitive elements in sensor 42. As explained with reference to FIGS. 2A-2C, each of the PMOS transistors in sensor 42 also forms a parasitic bipolar transistor that is inactive during normal operation. However if a large enough charge is deposited on the body region of the transistor, caused by one or more of the emitted charged particles passing through the body region, this charge can turn “on” the parasitic bipolar transistor of a MOS transistor that is biased in the “off” state.

When one or more of the parasitic bipolar transistors in sensor 42 turns on, this permits current to flow from voltage bias node VDD to latch node ND. The resulting current can deposit enough charge on latch node ND to change the state of latch 44. In addition, the MOS transistors in latch 44, itself, that are biased in the “off” state” can detect the emitted charged particles in a similar manner as the transistors in sensor 42. Each of the transistors in latch 44 similarly includes a parasitic bipolar transistor that can become forward biased in response to a “hit” by the emitted charged particles into the body of the transistor. When forward biased, these parasitic bipolar devices can deposit a sufficient charge onto latch nodes ND and D or remove a sufficient charge from these nodes to override the state of the “on” MOS transistor in inverter pair P0/N0 or P1/N1, which can force the inverters to change states.

For example, assume a “1” is in the latch, node D is high and node ND is low. In this case, P0 is “on”, N0 is “off”, P1 is “off”, N1 is “on”, and N2 and N3 are “off”. A large ion hit on N0 would briefly turn on N0 and pull node D low. The low voltage on node D causes inverter P1/N1 to drive node ND to a high, thereby changing the state of the latch. Similarly, a large ion hit on P1 would briefly turn on P1, pulling node ND high, causing inverter P0/N0 to drive node D low, thereby changing the state of the inverter. A large ion hit on transistor N3 would turn on transistor N3, pulling node ND high and causing inverter P0/N0 to drive node D low to change the state of the latch. A hit on P0 would cause no upset since the drain and source of P0 are both at a high voltage of VDD, and P0 is already in an on state. A hit on N1 would cause no upset since the drain and source of N1 are both at a low voltage of GND and N1 is already in an on state. Also a hit on N2 would cause no upset since the drain and source of N2 are both at a high voltage of VDD.

The operation of the circuit shown in FIG. 5 thus illustrates an example of a method of detecting a neutron, according to an aspect of the present disclosure. As described above, a neutron conversion material emits charged particles in response to a reaction of the neutron conversion material to a neutron. The latch is initialized to a first state, and a plurality of semiconductor sense elements are biased in an OFF state. The semiconductor sense elements are configured to produce a sense current in response to the charged particles. The sense current changes the state of the latch from the first state to a second, different state. The present state of the latch is then read to detect the change from the first state to the second state.

### 4. Extended-Area Charge Collection Plate

The following section describes a neutron detector comprising one or more sense elements having an extended-area detection plate and describes how it is different from both a traditional SRAM neutron detector and a detector formed of a latch that is driven by and array of charge-sensitive elements.

Either PMOS or NMOS transistors with their parasitic pnp or npn bipolar transistor can be used as sense elements. Detailed simulations would indicate which transistor type is most sensitive for a specific technology. A typical configuration for the PMOS sense element is shown in FIG. 4, and a similar argument could be applied to the “OFF” NMOS device. Two embodiments of this sense element will be described. In the conventional SRAM approach, the “OFF” PMOS device would be the sensitive element, for example. The second configuration, shown in FIG. 5, applies to an array of sensing elements configured such that an upset in any of a number of 1 to (n) sensing elements will be captured by a single latch. An extended-area detection plate can be incorporated in each of these cases.

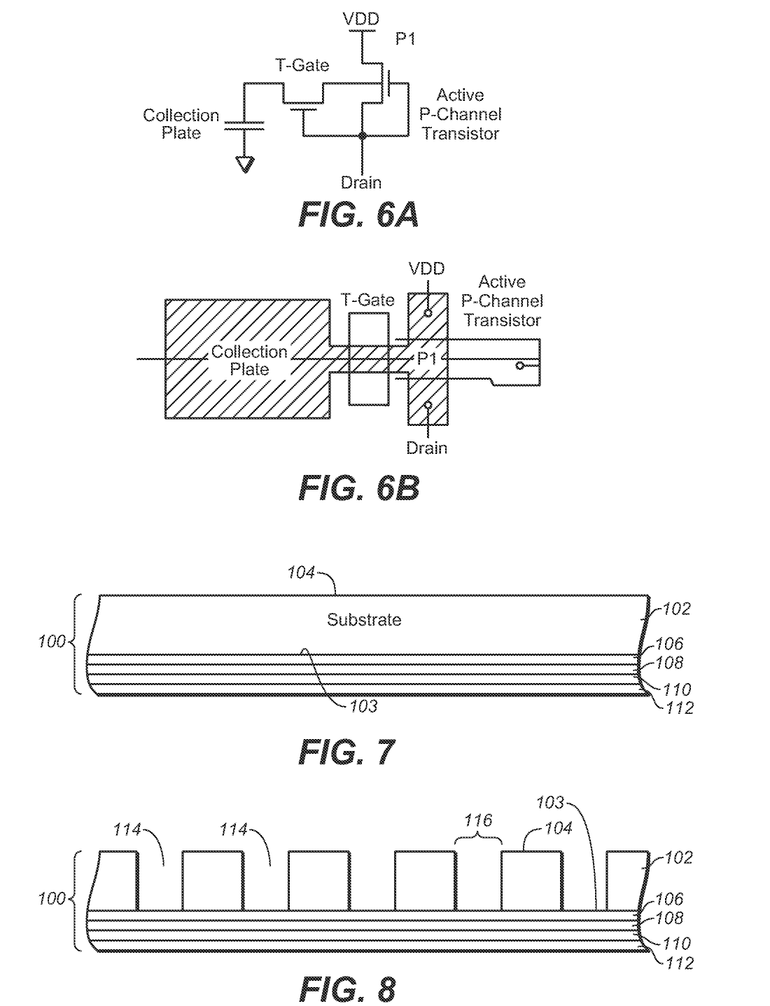

In an exemplary embodiment, the sensitive area for charged hits is extended to physical areas that are not under the active gate region. FIG. 6A illustrates a schematic of an exemplary embodiment where the sensitive body region of transistor P1 is extended by pulling out the floating body of the sense transistor by the use of a second transistor in a T-Gate configuration in series with a collection area of silicon material that forms an electrically-floating, charge-sensitive collection plate. FIG. 6B illustrates an exemplary layout of the embodiment shown in FIG. 6A. In this layout the T-gate transistor gate is common with the gate of the sensitive transistor. The body silicon is one single shape, pulled through the T-gate device to include the collection area silicon. In this embodiment, the T-gate transistor acts as a series body-resistor with the collection silicon. This collection plate silicon can be doped with the same implants as the well region under the gate. Depending on the process flow, this area may be coated with the same silicide that is applied to the source/drain areas and to the polysilicon. Charge that hits the silicon collection plate will create hole/electron pairs and the resulting charge will bias the floating-body of the ‘off’ device, causing it to go into bipolar conduction. This current flow, if the charge is greater than Qcrit, will cause the charge to be captured, either in the memory cell or in the connected latch.

Neutron detection efficiency is increased by adding the extended-area detection plate, as shown in the cross-hatched region of FIG. 6B, which increase the percentage of detection area as compared to the total area of the detection circuit. The detection transistor to which the plate is connected, for example a PMOS device, can be sized very small as part of an SRAM cell or as part of an element array of sensing devices. In that way, the switching speed of the latching element can be optimized and the Qcrit can be maintained to match the energy levels of the alpha and Li ion charges. The T-gate transistor could be designed to minimize the series resistance of that transistor. A high value of resistance (100 k ohms or more) could delay the coupled charge into the body, allowing recombination and reducing the effective charge that will reach the Qcrit level. An exemplary embodiment of the present disclosure is particularly effective in SOI (silicon on insulator) technology, for example. This technology has an absence of junction isolation capacitance and supports very large collection areas. The capacitance of a silicon island over buried oxide (Box), without poly or metal over-layers is several orders of magnitude lower in value than that of the body of the transistor with thin gate oxide and gate poly region. This allows the collection region to be much larger than the gate body while still acting equally as a charge collection plate. The collection region could be doped with the standard well doping of the sense transistor (N-well for the example of the PMOS device) with standard silicide coating applied. The implementation of the collection region in a square area will minimize charge distance to the active body but it is unclear how important this parameter will be as it is in series with a rather large T-gate resistor. Exemplary embodiments of this approach work equally well with PMOS or NMOS devices.

Other semiconductor sensing elements may be used in place of the PMOS sense transistors and the NMOS sense transistors. Such elements include, for example, actual bipolar transistors or diodes, as appropriate for the chosen technology, which can be designed to be sensitive to particle currents.

### 5. Fabrication of Detection Assembly

As mentioned previously, an aspect of the present disclosure relates to the manufacture of the detection assembly in which the neutron conversion structure is fabricated independently of and as a distinct component from the sensing element structure. Once manufactured, the neutron conversion structure can be appropriately sized for assembly with the sensing element structure. The neutron detection assembly is formed by joining the thermal neutron conversion structure and the sensing element structure by use of an adhesive, for example. In one embodiment, the assembled neutron detector is in a die form, which can then be assembled into an IC package following typical package assembly processes.

5.1 Sensing Element Structure

FIG. 7 illustrates a cross-sectional view of a sensing element structure 100 at an intermediate step in the fabrication process. Similar to the embodiment shown in FIG. 1, sensing element structure 100 includes substrate 102, which includes a first, front surface 103 and a second, back surface 104. Substrate 102 may include elements such as an SOI substrate and a base handle wafer or die. A plurality of layers are fabricated onto front surface 103, including for example a Box insulating layer 106, an active silicon layer 108, one or more interconnect layers 110 and a passivation layer 112.

In one example, active silicon layer 108 includes one or more sense elements, such as the one or more sense elements of charged particle sensor 42 shown in FIGS. 3 and 4, the latch 44 shown in FIGS. 3 and 4, and/or the memory cell 60 shown in FIG. 4. The active silicon layer may also include at least one of the control circuit 46 or the memory 48 shown in FIG. 4.

In one embodiment, the sensing element structure if fabricated as an integrated circuit processed on a CMOS Silicon-on-Insulator (SOI) wafer, for example a 90 nm SOI process, manufactured by a commercial silicon foundry. It contains a functional circuit to process the data generated by one or more alpha and lithium ion sensing elements or a large array of alpha and Li ion sensing elements, and to communicate those results under program control through a serial link, for example.

FIG. 8 illustrates a cross-sectional view of sensing element structure 100 at a subsequent processing step in which one or more windows 114 are etched or otherwise formed into substrate 102, either at the wafer level or at the die level. In the example shown in FIG. 8, windows 114 extend through the entire thickness of substrate 102, to the surface of BOX insulating layer 106. In another example, windows 114 extend through only a portion of the thickness of substrate 102 such that the windows do not extend completely to the insulating layer 106. Windows 114 create pathways for charged particles (such as alpha particles and Lithium ions) to travel from the neutron conversion structure (shown in FIG. 1) to the sense elements in active semiconductor layer 108. In a later fabrication step, windows 114 may be partially or completely filled with a gap fill medium that has a lower stopping power for alpha particles and Lithium ions than does the material of substrate 102. This gap fill medium can include, for example, a vacuum, air, or other low-density gas, for example, which provides a long mean free path for alpha particles to minimize attenuation through the structure.

The windows 114 may be aligned over respective single sensing elements (as shown in FIG. 1), an array of sensing elements (such as sensing elements of charged particle sensor 42 shown in FIG. 5), and/or memory cell 60/latch 44 shown in FIGS. 4 and 5). The vertical walls of the windows 114 in FIG. 5 are shown for simplicity. Windows 114 are aligned vertically over the respective sensing element(s) such that each window 114 overlaps at least a portion of the surface area (such as the entire surface area) of the respective sensing element(s) in a plane parallel to front surface 103 of substrate 102. In a further embodiment, a single window 114 may overlap all of the semiconductor elements forming one or more of the neutron detector circuits 40 shown in FIG. 5. In yet a further embodiment, the windows 114 may be aligned to overlap partially or entirely one or more of the extended-area collection plates shown in FIGS. 6A and 6B. The windows 114 may have a cross-sectional area (represented by bracket 116) in a plane parallel to the active semiconductor layer 108 that is limited to overlap only a single sensing elements, an array of sensing elements (such as the array of sensing elements in charged particle sensor 42 in FIGS. 3 and 4), a single detector circuit 4, or a plurality of detector circuits 40 without overlapping the semiconductor elements of surrounding circuitry, for example.

The pattern of the web that remains over the array may be designed to add structural stability to the etched wafer and die. An adhesive layer may be used to merge this sensing element structure to the neutron conversion structure in a future step.

5.2 Neutron Conversion Structure

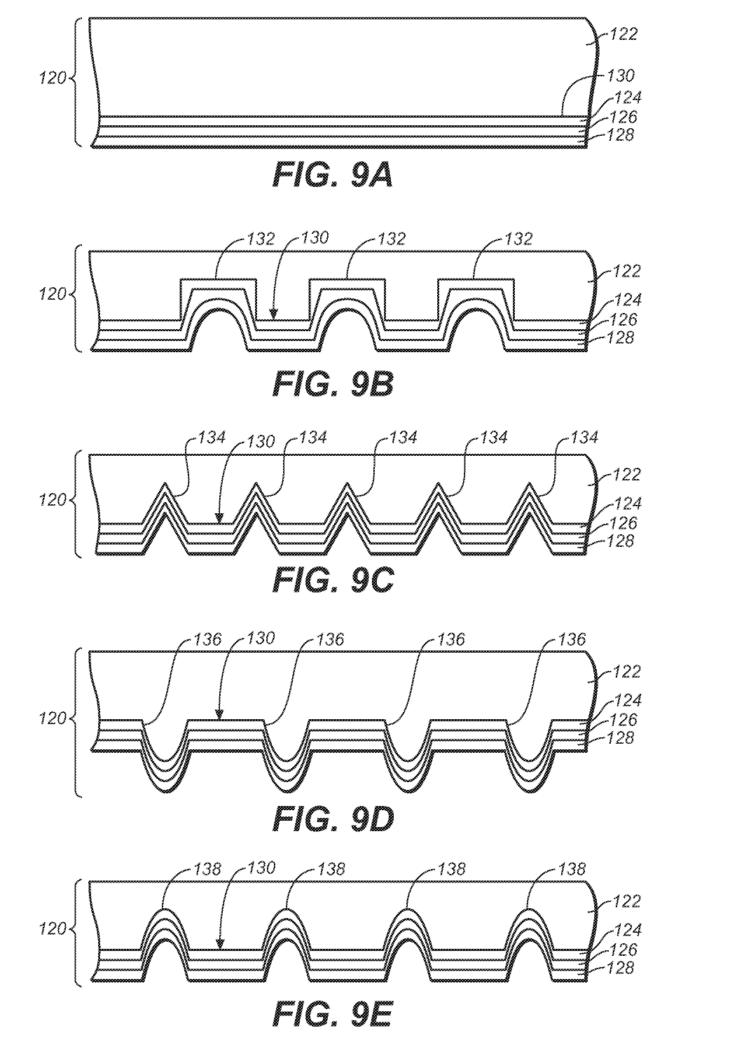

FIG. 9A illustrates a cross-sectional view of a neutron conversion structure 120 prior to assembly with a fabricated sensing element structure 100, shown in FIG. 8.

Neutron conversion structure 120 includes a base layer (or substrate) 122, which may include silicon, plastic, glass, or other structurally sound material. The thickness of this layer is not critical to the function of this device in at least one embodiment. Some factors used to select a material for base layer 122 in an exemplary embodiment include sufficient structural integrity such that the subsequently applied layers do not deform the base layer and a thermal coefficient of expansion that is compatible with the sensing element structure 100 to which the device is being adjoined so that no thermal induced fractures to the silicon occur. An insulator layer 124 may be deposited on base layer 122, which promotes good adhesion to the base layer 122. The insulator layer 124 may include silicon nitride, silicon dioxide, or any other material in that class of dielectrics, for example. Thermal neutron conversion material 126 is deposited or otherwise applied or attached to insulator layer 124 (or directly to base layer 122).

In a simple form, thermal neutron conversion layer 126 consists or consists essentially of enriched Boron-10. Pure Boron-10 is known to have poor adhesion properties because the atoms have a poor self-affinity and will disassociate back into a powder after being put under enormous pressure. Therefore, in another embodiment, the Boron-10 of thermal neutron conversion layer 126 has the form of enriched boron carbide. This material can be deposited using physical vapor deposition, e-beam deposition, sputtering, or other production processes. The thermal neutron conversion layer 126 can also be formed with a composite structure by first depositing at least one of lithium fluoride, an insulating layer, or enriched boron carbide. This composite structure has the benefit of increasing the thermal neutron conversion efficiency of this structure by greater than 200% in an exemplary embodiment. In an exemplary embodiment, the neutron conversion material therefore consists or consists essentially of Boron-10, enriched boron carbide, Lithium-6 (Li6), Lithium-6F (Li6F), enriched Lithium Fluoride (LiF), Gadolinium 257 (and richer), or any combination thereof.

The size, shape, spacing and thickness of conversion layer 126 are variable according to the specific embodiment to achieve an optimum solution of greatest efficiency. The thickness of the conversion layer determines the probability that a given neutron passing through the conversion layer will react with a Boron 10 atom. The greater the thickness, the greater the probability of a reaction. However, increasing the thickness can have diminishing returns. As the thickness increases, alpha particles or Lithium ions reacting with Boron 10 atoms that are positioned further away from a particular sensing element have a reduced probability of passing through the sensing element. Also, the alpha particles and Lithium ions must pass through a greater amount of material to reach the sensing element, which increases the probability of being absorbed by the conversion layer and not reaching the sensing element. In an exemplary embodiment, the conversion layer 126 has a thickness of 2.5 microns or less, such as 2 microns. However, other thicknesses can be used in other embodiments.

The final layer deposition is called a passivation layer 128. This layer provides a protective barrier for the thermal neutron conversion layer 126 and provides a surface for an adjoining adhesive. The passivation layer 128 may include, for example, a thin oxide, a silicon nitride or a sandwich of both materials. Other materials may also be used. In one example, the passivation layer 128 is made as thin as possible so as to limit the thickness of material that may absorb alpha particles and/or Lithium ions, between the neutron “hit” and the sensing element(s).

Neutron conversion structure 120 may be manufactured and screened to ensure that only devices meeting the production specifications are used in the manufacture of the overall sensor. In the embodiment shown in FIG. 9A, the base layer 122 of neutron conversion structure 120 forms a planar surface 130 on which to deposit the various subsequent layers 124, 126 and 128.

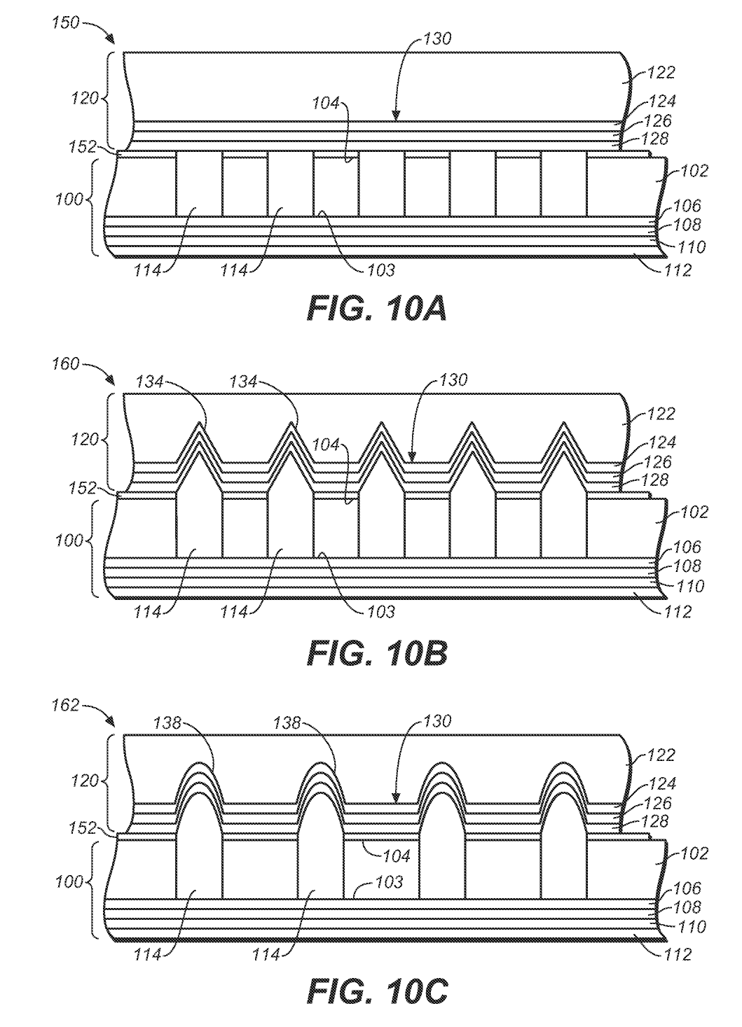

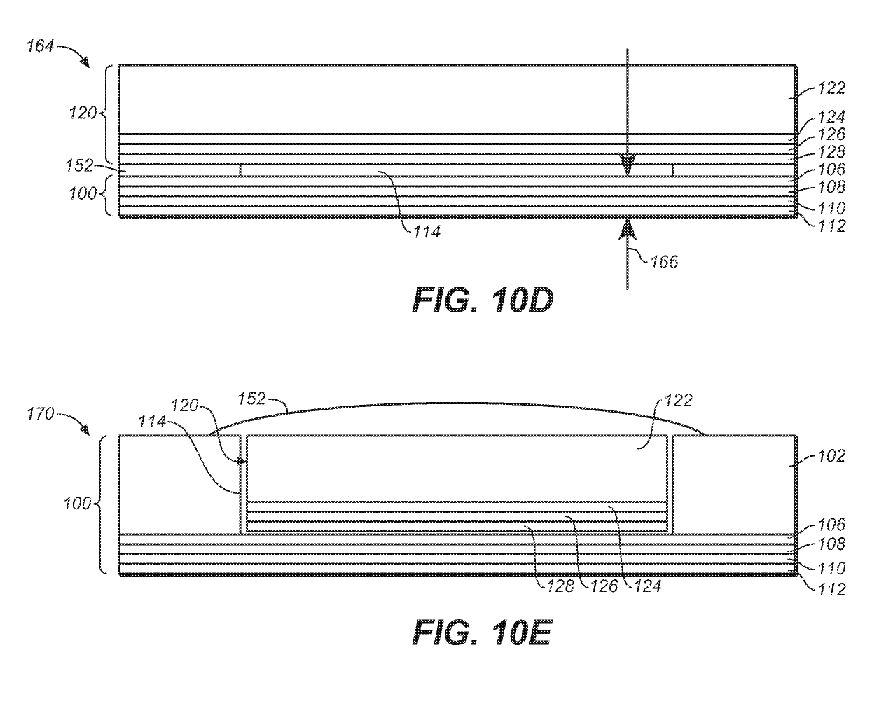

FIG. 9B illustrates a cross sectional view of neutron conversion structure 120 according to an alternative embodiment in which the surface 130 of base layer 122 is formed with a topology pattern prior to depositing layers 124, 126 and 128. The topology may be formed by any suitable process such as a material additive or subtractive process, including but not limited to photolithography processes. In this embodiment, the topology pattern includes a plurality of rectangular grooves or trenches 132 that may provide areas to enable improved conversion efficiency, in some embodiments. For example, trenches 132 may provide a greater surface area of neutron conversion material adjacent to the windows 114 formed in the sensing element structure, as discussed below with reference to FIG. 10A. This may result in a greater percentage of alpha particles and/or Lithium ions being directed within windows 114. In this embodiment, the trenches 132 are parallel to one another. However the increase in efficiency may be limited in some cases since alpha particles are emitted in random directions and the may be absorbed by adjacent surface topology.

FIG. 9C illustrates a cross sectional view of neutron conversion structure 120 according to another alternative embodiment in which surface 130 of base layer 122 is formed with a plurality of parallel V-shaped grooves or trenches 134 that may provide areas to enable improved conversion efficiency, in some embodiments as mentioned with respect to FIG. 9B.

FIG. 9D illustrates a cross sectional view of neutron conversion structure 120 according to another alternative embodiment in which surface 130 of base layer 122 is formed with a plurality of elongated, parallel parabolic (or other curvilinear) shaped protrusions 136 that may provide areas to enable improved conversion efficiency, in some embodiments as mentioned with respect to FIG. 9B.

FIG. 9E illustrates a cross sectional view of neutron conversion structure 120 according to another alternative embodiment in which surface 130 of base layer 122 is formed with a plurality of elongated, parallel parabolic (or other curvilinear) shaped depressions 138 that may provide areas to enable improved conversion efficiency, in some embodiments as mentioned with respect to FIG. 9B.

In further embodiments, the depressions or protrusions may be non-parallel to one another. In even further embodiments, the depressions or protrusions shown in FIGS. 9B-9E may be formed as regularly or irregularly spaced discrete depressions or protrusions.

As shown in FIGS. 9A-9C, one exemplary benefit of fabricating the neutron conversion structure and the sensing element structure separately form one another is that is the base material, insulators, conversion materials, and protective layers of one structure can be optimized independently of the layers of the other structure. Thus, the production yield of combined detector assembly is dependent primarily on the yield associated with adhesion between the two structures. Also, separate fabrication reduces the stress that the neutron conversion material would otherwise place on the sensing element structure. As die sizes increase, this stress can cause stress fractures in the sensing element wafer. By manufacturing the two structures separately, the stress between the two structures, such as that caused by different coefficients of thermal expansion during heating and cooling, can be reduced. With independent manufacture, die sizes can be increased and later bonded together with minimal added stress to either die. This may increase manufacturing and detection efficiency of the combined structures.

5.3 Assembled Neutron Detector

FIG. 10A illustrates a cross sectional view of an assembled neutron detector 150, according to an exemplary embodiment of the disclosure. Neutron detector 150 includes a pre-fabricated sensing element structure 100 attached to a pre-fabricated neutron conversion structure 120 with an adhesive 152, for example. In this embodiment, neutron conversion structure 120 is adhered to the back surface 104 of substrate 102 of sensing element structure 100 instead being fabricated with additional layers on front surface 103.

As mentioned above, windows 114 provide paths for alpha particles and Lithium ions to travel more freely from neutron conversion layer 126 to the bodies of the sensing elements within active silicon layer 108 when created following a neutron “hit” within the neutron conversion layer. Each window or cavity 114 can be sized and positioned to align vertically with a single MOS transistor structure of a sensing element in active semiconductor layer 108, or can be sized and positioned to align vertically with a plurality of MOS transistor structures. In one example, the windows 114 are vertically aligned with the channels of the MOS transistors. In one example, a window 114 may cover an entire array of sense transistor, or may be divided into a plurality of windows depending on how the array is laid out. For example, there may be a wide power and ground bus in the middle of the sensor element array, between separate windows. Since only the arrays need to be reachable by alpha particles, two windows 114 may be formed in this situation, for example.

The neutron conversion structure 120 may be attached to or otherwise positioned relative to sensing element structure 100 by adhesive 152 or any other suitable attachment method. In one example, adhesive 152 includes a standard semiconductor epoxy. The neutron conversion structure 120 may be attached to sensing element structure 100 at the wafer level or at the die level. If attached at the wafer level, the two wafers forming structures 100 and 120 may be adhered together and subsequently cut into individual detector assembly die, which may later be assembled into an integrated circuit (IC) package and mounted to a circuit board forming a final neutron detector product, for example. In an alternative embodiment, the wafers forming the neutron conversion structure 120 and the sensing element structure 100 are individually cut into separate die, which are subsequently paired and adhered together to form individual detector assembly die.

During assembly, windows 114 may be filled with a gap fill medium, such as a gas, as discussed in more detail below. Each window 114 is sealed by adhesive 152 between sensing element structure 100 and neutron conversion structure 120. Therefore, the gas introduced into windows 114 during assembly becomes sealed within the windows.

In another embodiment, a further neutron conversion structure (not shown in FIG. 10A) may be fabricated independently of sensing element structure 100 and then attached to the front surface of sensing element structure 100, opposite to the neutron conversion structure 120. But since the resultant alpha particles and Lithium ions can only go 3-5 microns into silicon before they are absorbed, and since metals might divert their travel direction, the various layers in sensing element structure 100 may limit the effectiveness of such a further conversion structure. Thus, a layout may be created having an area above the sensing area that is void of metals. Also, this area may be etched or partially etched to reduce the thickness of the material over the sensing element(s). For example, this area could be post-processed to remove the isolation layers and passivation layers to reduce the thickness of material over the sensing element(s) to under 2-3 microns.

FIG. 10B illustrates a cross sectional view of an assembled neutron detector 160, according to another embodiment in which the base layer 122 of neutron conversion structure 120 has a surface 130 with V-shaped trenches 134, which are aligned with the windows 114 formed in substrate 102 of sensing element structure 100 during assembly. As shown in FIG. 10B, trenches 134 may provide a greater surface area of neutron conversion material adjacent to the windows 114 formed in the sensing element structure. This may result in a greater percentage of alpha particles and/or Lithium ions being directed within windows 114.

FIG. 10C illustrates a cross sectional view of an assembled neutron detector 162 according to another embodiment in which the base layer 122 of neutron conversion structure 120 has a surface 130 with parabolic shaped trenches 138, which are aligned with the windows 114 formed in substrate 102 of sensing element structure 100 during assembly. Again, trenches 138 may provide a greater surface area of neutron conversion material adjacent to the windows 114 formed in the sensing element structure.

FIG. 10D illustrates a cross sectional view of an assembled neutron detector 164 according to another embodiment in which the thickness 166 of substrate 102 of sensing element structure 100 is reduced, by removing the substrate 102 (shown in FIGS. 10A-10C) to reduce the amount of substrate material through which the alpha particles and Lithium ions must travel to reach the sensing elements formed in active semiconductor layer 108. Substrate 102 (or a partial thickness of the substrate) may be reduced by etching, lapping or any other suitable material removal process. A temporary handling wafer may be attached to the front surface of sensing element structure 100 to provide structural integrity during the material removal process and while adjoining structures 100 and 120 together. Neutron conversion structure 120 is adhered to sensing element assembly 100 by an adhesive 152, for example. At least one window 114 defined by a lack of adhesive within the window, wherein the thickness of adhesive 152 defines the height of window 114. Again the window 114 is aligned with one or more sensing elements within active semiconductor layer 108. In one example, adhesive 152 is applied only along the perimeter of structures 100 and 120, leaving the middle region between the structures, which overlaps the neutron detector circuitry, free of adhesive and open to window 114. On another embodiment, a plurality of windows is formed by a plurality of areas that are free of adhesive. One or more of the windows in any of the embodiments described herein may be filled with a gap fill medium, as discussed below. Placing the neutron conversion layer 126 very close to the semiconductor layer 108 (by removal of substrate 102) increases the range of angles at which emitted alpha particles and/or Lithium ions will pass through a sensing element within layer 108, which increases the probability that a particular emitted alpha particle or Lithium ion will be detected.

FIG. 10E illustrates a cross sectional view of an assembled neutron detector 170 according to another embodiment in which the substrate 102 of sensing element structure 100 has a window 114 of removed material, and neutron conversion structure 120 is sized to fit within window 114 as an insert. Structure 120 has a length and width that are less than a corresponding length and width of window 114 so that structure 120 may fit within the window. An adhesive 152 may be applied over structure 120 or along the perimeters of structure 120 to adhere the structure 120 to structure 100. The neutron conversion structure 120 may have a height that is equal to the height of window 114, as shown in FIG. 10E or may have a height that is greater than or less than that of window 114. In a particular embodiment, neutron conversion structure 120 has a height that is approximately 2 mils less that the height of window recess 114. The neutron conversion structure may be joined to the sensing element structure by, for example, placing a strip of high temperature tape across the top of the substrate 122 of neutron conversion structure 120 and positioning the neutron conversion structure within window 114 such that the tape bridges the gap between substrate 122 and substrate 102 of sensing element structure 100. Adhesive 152 may then be applied and cured, and then the tape may be removed. This positions the neutron conversion material 126 very close to the sensing elements within semiconductor layer 108 without having the neutron conversion structure touch and possibly scratch insulation layer 106, due to the approximately 1-2 mil gap between the two structures.

In the embodiment shown in FIG. 10E, the depth of window 114 is equal to the thickness of substrate 102, such that the window 114 extends through the entire substrate layer, to insulating layer 106. Again, placing the neutron conversion layer 126 very close to the semiconductor layer 108 increases the range of angles at which emitted alpha particles and/or Lithium ions will pass through a sensing element within layer 108, which increases the probability that a particular emitted alpha particle or Lithium ion will be detected.

As discussed above, separate fabrication reduces the stress that the neutron conversion material would otherwise place on the sensing element structure. As die sizes increase, this stress can cause stress fractures in the sensing element wafer. By manufacturing the two structures separately, the stress between the two structures, such as that caused by different coefficients of thermal expansion during heating and cooling, can be reduced. With independent manufacture, die size of neutron conversion structure 120 (and the corresponding size of window 114 can be increased with minimal or no added stress to either die. This may increase manufacturing and detection efficiency of the combined structures. Thus, larger arrays of sensing element structures may be fabricated adjacent the window 114, which may be covered by a larger conversion structure die 120 to achieve improvements to detection probabilities.

If the neutron conversion structure were fabricated directly on sensing element structure 100, the resulting stress between the structures may limit the size of window 114 to a maximum of about 8 square millimeters, for example, without causing cracks in the oxide layer. With an embodiment shown in FIG. 10E, the size of window 114 and the corresponding neutron conversion structure die may be 1 square centimeter or more. Also, a particular sensing element structure may have multiple windows 114 and corresponding neutron conversion structure die 120.

5.4 Gap Fill Medium

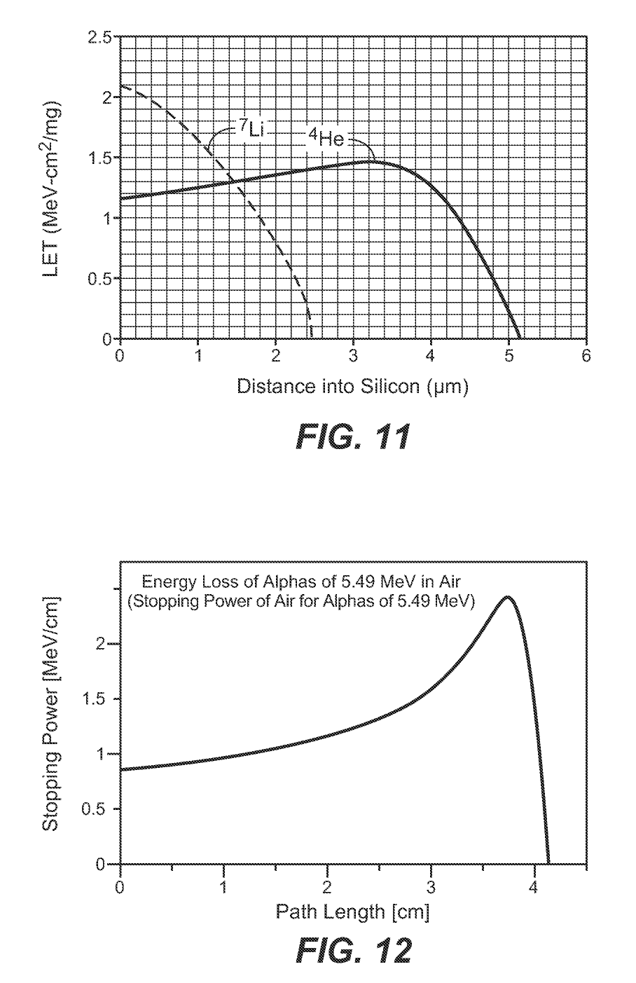

Windows 114 are formed in the substrate of sensing element structure 100 so that the alpha particles and Lithium ions can more easily reach the sensing elements within the active semiconductor layer 108. FIG. 11 illustrates the distance alpha particles and Lithium ions can travel through silicon, which is a common material with which semiconductor substrates are fabricated. The short alpha particle and Lithium ion travel distance through silicon is why the silicon is removed above the sensor structures. However, such material removal is not required in all embodiments of the present disclosure.

In order to maintain a long mean free path of travel for the alph particles and Lithium ions, the cavity formed by one or more of the windows 114 may be filled with a gap fill medium that has a low stopping power for alpha particles and/or Lithium ions. This gap fill medium can be a vacuum, air, or other low density gas, for example, which provides a long mean free path for alpha particles and Lithium ions to minimize attenuation through the structure.

As a thermal neutron arrives at the neutron conversion layer 126, there is a probability of the neutron reacting with the large cross-section of materials like Boron-10 and/or Lithium-6, for example. For example, a neutron reaction with Boron-10 generates alpha particles and Lithium ions, which may split in opposite directions from each other and can go in any direction. The energy levels of the emitted alpha particles and Lithium ions are 1.47 MeV and 0.84 MeV, respectively.

Again, FIG. 11 illustrates the alpha particle and Lithium ion range of travel in silicon when a thermal neutron is captured by Boron-10. An exemplary useful travel range of these ions in silicon is 1 micrometer to 4 micrometers due the high density of the silicon material. This short useful range might lead one to consider placing the thermal neutron conversion layer in close very proximity to the sensing elements within the active semiconductor layer, but this short useful range is only for materials with high density. By removing silicon material from the substrate 102 and filling the resulting gaps (e.g., windows 114) with a less dense material, the neutron conversion material may be placed at greater distances from the active semiconductor layer, while still maintaining a sufficiently long mean free travel path for the alpha particles and Lithium ions. In any case, for exemplary embodiments, the thickness of high density materials between neutron conversion material 126 and the sensing elements is kept to 4 micrometers or less.

FIG. 12 is a graph that illustrates a Bragg curve, which shows the range of an alpha particle in a low-density media such as air. When the alpha particle travels through a low-density medium such as air, helium, nitrogen, other gases or a vacuum, the mean free path for the alpha particle is more than 1000 times longer than through silicon. This low-density medium may be used within windows 114 to minimize the stopping power of the medium between the thermal neutron conversion layer 126 and the sensing elements within semiconductor layer 108.

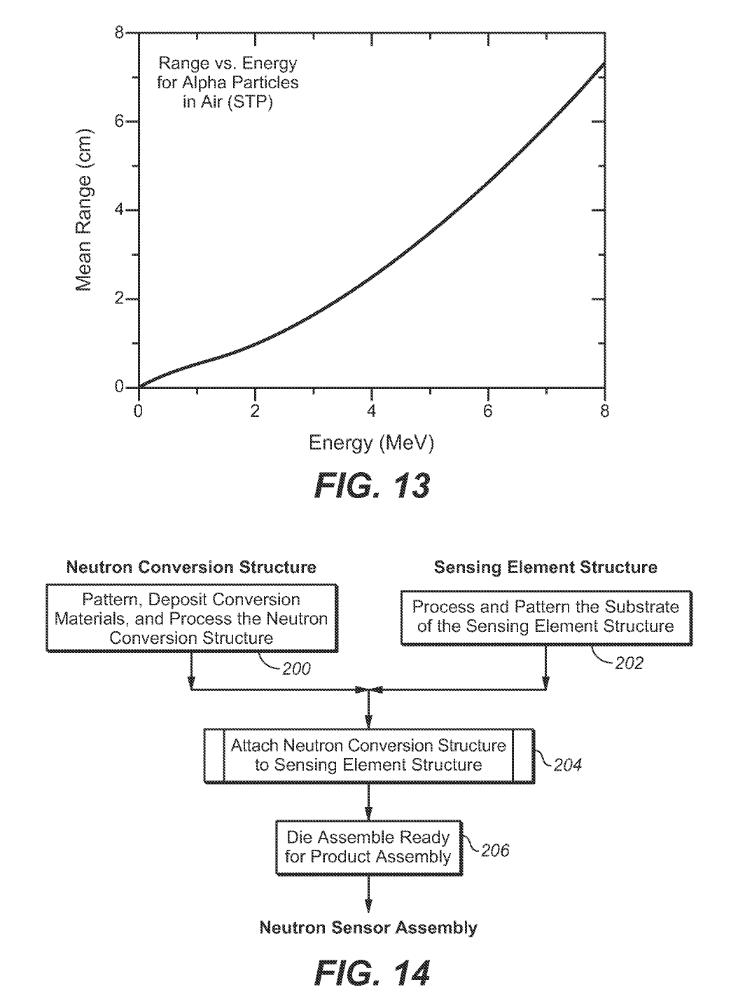

FIG. 13 is a graph that illustrates the mean free path of an alpha particle of various energy levels. The mean free path of the alpha particle of 1.47 MeV goes from 3.9 micrometers when the medium is silicon to 7,530 micrometers when the media is air. The mean free path of a Lithium ion of 0.84 MeV goes from 2.4 micrometers when the medium is silicon to 4,700 micrometers when the media is air. This provides a large improvement in the mean free path to enable the thermal neutron conversion structure 120 to be a substantial distance from the sensing elements within the active semiconductor layer 108.

The following table illustrates densities of various potential gap fill media gases along with the range of alpha particles and Lithium ions in these gases. The energy levels of the emitted alpha particles and Lithium ions are 1.47 MeV and 0.84 MeV, respectively. Helium, Hydrogen, and Neon gases provide large increases in the mean free path, which further reduces the energy loss by traveling through the length of that medium. The use of a vacuum to reduce the pressure in the gap cavity would also greatly reduce the energy loss of the ions traveling through that gap fill medium.

### Charged Particle Range in Different Gap Fill Media

| | Density | Li Ion | | Alpha Particle | |
|---|---|---|---|---|---|
| Gas | g/cm³ | 0.84 MeV | | 1.47 MeV | |
| Air | 0.00120 | 4.70 | mm | 7.53 | mm |
| Nitrogen | 0.00125 | 4.80 | mm | 7.11 | mm |
| Oxygen | 0.00143 | 4.66 | mm | 7.00 | mm |
| Hydrogen | 0.00009 | 19.18 | mm | 26.68 | mm |
| Helium | 0.00018 | 30.75 | mm | 39.48 | mm |
| Neon | 0.00090 | 10.60 | mm | 14.83 | mm |
| Argon | 0.00178 | 4.80 | mm | 7.81 | mm |
| Krypton | 0.00374 | 3.61 | mm | 6.13 | mm |
| Xenon | 0.00589 | 2.32 | mm | 4.28 | mm |
| CO | 0.00117 | 4.98 | mm | 9.02 | mm |

5.5 Example Assembly Process

FIG. 14 is a flow diagram, which illustrates the basic steps for creating a neutron detector assembly utilizing two independent structures, according to an exemplary embodiment of the present disclosure. At step 200, a neutron conversion structure is fabricated by manufacturing a base layer that has good structural integrity such as silicon, plastic, glass, or other material that can be used in a mass production process. Then one or more layers are deposited or otherwise placed on the base layer. As shown in FIG. 9A, for example, these layers may include an insulation layer 124, a neutron conversion layer 126 and a passivation layer 128. The surface topology of the base layer may be planar or have a deterministic structure to enhance the neutron conversion efficiency, for example.

At step 202, a sensing element structure is fabricated on a substrate 102, such as that shown in FIGS. 7 and 8 by integrated circuit fabrication techniques. The substrate 102 may have various layers deposited on a first surface 103 of the substrate, such as a box insulating layer 106, an active semiconductor layer 108, interconnect layers 110 and a passivation layer 112. A second, opposite surface 104 of substrate 102 is processed to thin the substrate and/or form one or more windows or cavities 114 within the substrate as shown in FIG. 8. For example, sensing element structure may be fabricated while in wafer or die form, for example.

One or both of the neutron conversion structure or the sensing elements structure are then inspected and/or tested to ensure that only fully functional devices are adjoined to form a neutron detection assembly. For example, the structures may be visually inspected and/or electrically tested to ensure functionality. The various sensing elements and electrical circuits formed within the sensing element structure may be tested under various conditions using typical IC functionality testing, such as by using embedded test circuits. Assuming both structures pass their respective verification procedures, the two structures are adjoined using an adhesive, for example, at step 204. The bonding between the two structures may occur in a vacuum, air, or other low density gas environment to ensure the window cavities 114 contain a medium with a low stopping power for the charged particles (for example). In an alternative embodiment, the window cavities are filled with a low-density solid material. At step 206, the resulting wafer or die assembly may be processed further using conventional wire bonded or flip chip assembly manufacturing, for example. If the attachment step 24 is performed at the wafer level, the wafer may be divided into individual die, prior to final product assembly at step 206.

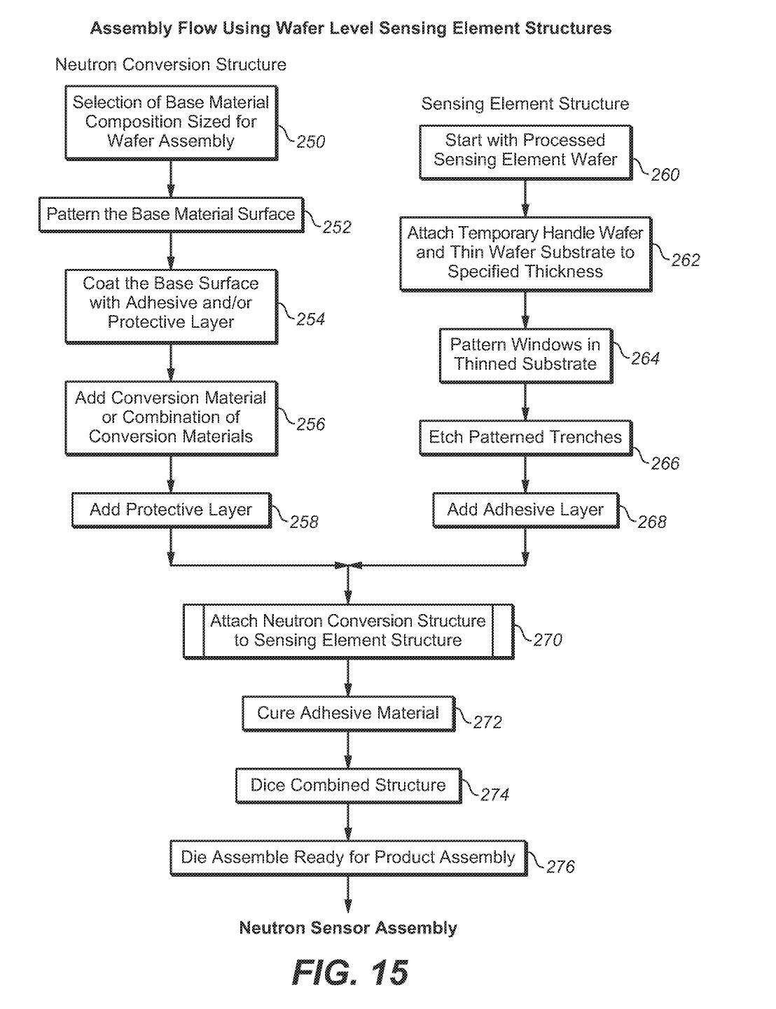

FIG. 15 is a flow diagram, which illustrates the basic steps for creating a neutron detector assembly at the wafer level, according to an exemplary embodiment of the present disclosure. At step 250, the base material composition is selected for the base layer substrate of the neutron conversion structure, and the substrate is sized for wafer assembly. For example, the neutron conversion structure may be fabricated on a single structure with a size matching that of a sensing element structure wafer. Possible sizes may include 6″, 8″, 10″, and 12″ diameter wafers.

At steps 252-258, the base substrate is processed to form the desired topology, and the various insulator, conversion material and passivation layers are applied to the resulting surface.

The sensing element structure is fabricated, beginning at step 260, where a wafer substrate is processed to include the various layers such as a box insulating layer, an active semiconductor layer (including the charged particle sensing elements), interconnect layers and a passivation layer, thereby forming a processed sensing element wafer. At step 262, a temporary handling wafer is attached to the front surface of the processed sensing element wafer, and the back side of the sensing element wafer substrate is thinned to a desired thickness. The wafer may be thinned by back grinding and polishing the sensing element wafer substrate, for example. The desired thickness may be determined by the method of future assembly, for example 5 mils for a wire-bond assembly and 11 mils for flip-chip assembly. Other thicknesses may also be used for these and other methods of assembly. This is done by standard semiconductor processing methods. After thinning, the temporary handling wafer is removed.

At step 264, the thinned wafer is patterned on the backside, with one or more windows aligned with the sensing elements within the active semiconductor layer. These windows are then cut or etched through the silicon substrate, at step 266, as shown in FIG. 7 for example, by using any of several semiconductor methods, for example XeF₂. The etching may extend entirely through the silicon substrate and stop at the insulating layer known as a Box layer, for example. In an alternative embodiment, the windows are etched through only a portion of the substrate silicon layer 20 such that the windows do not extend completely to the insulating layer. The windows may be aligned over a single sensing element, an array of sensing elements a combination of arrays of sensing elements, for example. The vertical walls of the windows shown in FIG. 8 are shown for simplicity. The pattern of the web of substrate material that remains over the active semiconductor layer may be configured to add structural stability to the etched wafer and die.

At step 268, an adhesive layer may be applied to the surface of the remaining substrate material, with care taken to leave the etched windows free from adhesive. In an alternative embodiment, the adhesive is applied to the corresponding surface of the neutron conversion structure or may applied to the surfaces of both structures.

At step 270, the neutron conversion structure is placed on top of the sensing element wafer such that the etched windows are covered by the neutron conversion layer. The adhesive is cured at step 272. Other methods of attachment can also be used. Once cured, the wafer can be diced into individual die at step 274 using standard silicon wafer dicing methods, for example. Each die forms a neutron sensor device. The neutron sensor die can then be assembled into an IC package at step 276 and used in a final neutron detector product.

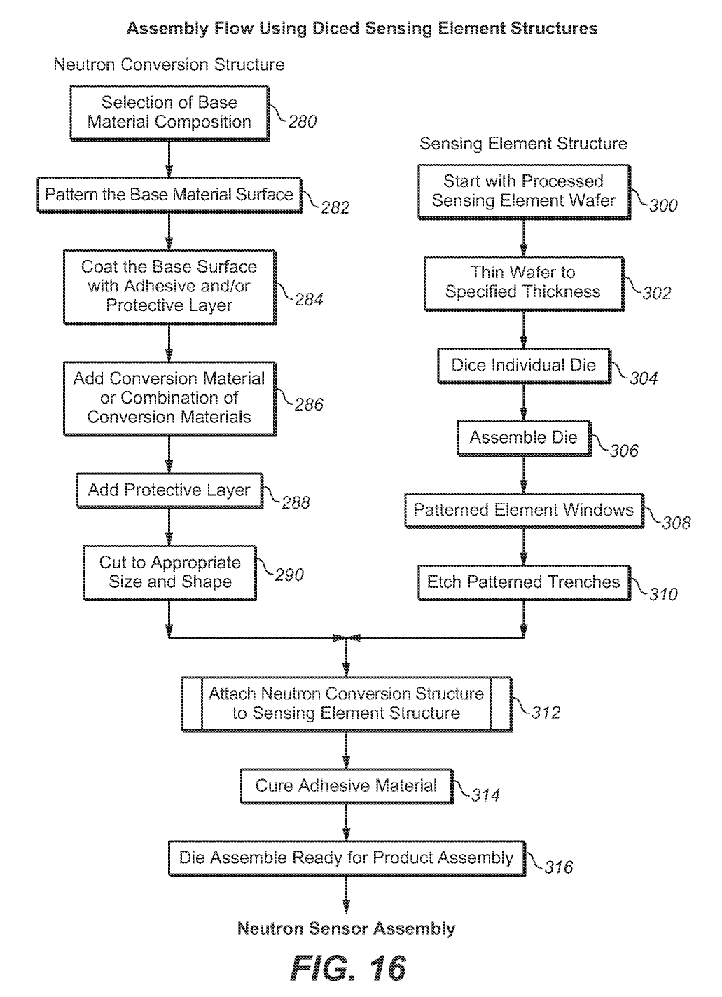

FIG. 16 is a flow diagram, which illustrates the basic steps for creating a neutron detector assembly at the die level, according to an exemplary embodiment of the present disclosure. At step 280, the base material composition is selected for the base layer substrate of the neutron conversion structure. At steps 282-288, the base layer substrate is processed to form the desired topology, and the various insulator, conversion material and passivation layers are applied to the resulting surface. At step 290, the neutron conversion structure is cut to an appropriate size and shape to mate with a corresponding sensing element die. For example a large base substrate comprising the deposited material conversion material may be diced into individual neutron conversion die having the same size as a corresponding sensing element die.

At step 300, a sensing element wafer is processed, distinct from the neutron conversion structure. The wafer may be thinned at step 302 to a desired thickness as discussed above. At step 304, the sensing element wafer is diced into individual sensing element die. These die are then assembled on a fixture at step 306, prior to patterning and window etching, at steps 308 and 310.

An adhesive layer may then be applied to the surface of the remaining substrate material on the sensing element die, on the neutron conversion die or on both die. Again, care is taken to avoid placing adhesive within the etched windows, for example.

At step 312, a neutron conversion die is placed on top of a corresponding sensing element die such that the etched windows are covered by the neutron conversion layer. The adhesive is cured at step 314. Other methods of attachment can also be used. Once cured, each die assembly forms a neutron sensor device. The neutron detector die can then be assembled into an IC package at step 316 to form a neutron detector IC chip and used in a final neutron detector product.

In the process flows shown in FIGS. 14-16, the manufacturing processes for fabricating the sensing element structure and etching away the silicon over the active areas can therefore be performed on the wafer or at the die level, and this process is independent of the manufacturing of the neutron conversion structure.

6. Increased Detection Ability with Multiple Assemblies

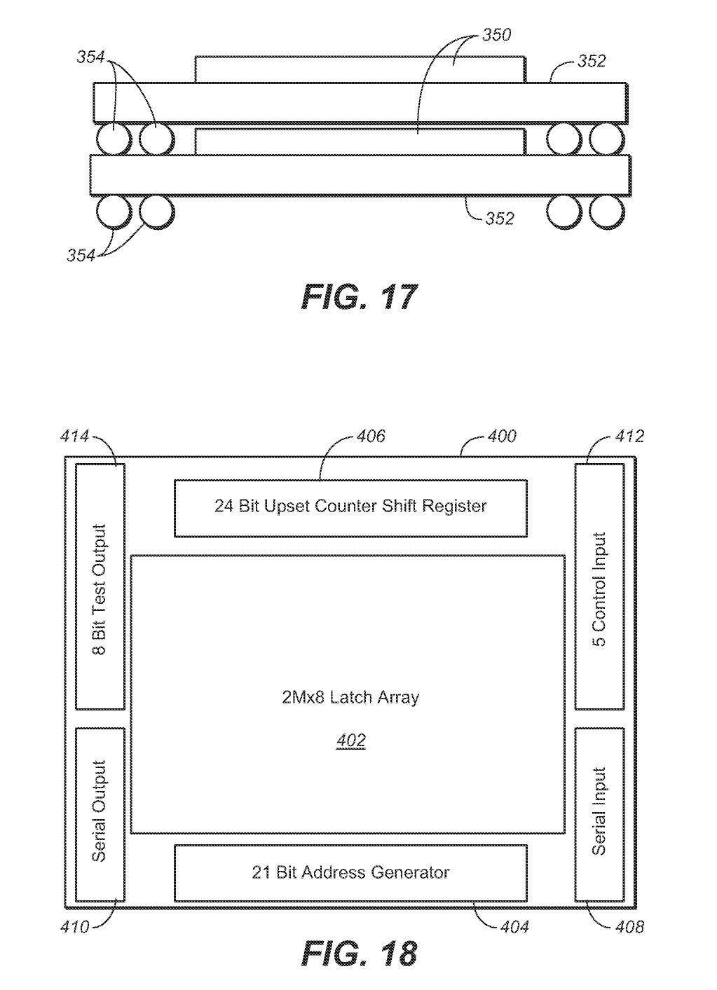

The detector efficiency of a neutron detector chip can be improved by increasing the number of neutron detector chip assemblies. This can be done by placing more assemblies on a printed circuit board, stacking multiple printed circuit boards, or by stacking assemblies on top of each other using any method of 3-dimensional circuit packaging. An example of two assemblies stacked together is shown in FIG. 17. In this figure, a combined neutron detection die assembly 350 is placed in an integrated circuit package 352 having solder ball leads 354. In one embodiment, the resulting IC package has a small number of input-output leads such that a multiple IC packages 352 may be stacked upon one another, as shown in FIG. 17. Various other methods of stacking or assembling multiple IC die may be used in other embodiments.

### 7. Neutron Detector Chip

FIG. 128 is a diagram illustrating a sample layout of circuit elements that are formed on the sensing element structure within the active semiconductor layer and the various interconnect layers, and can be assembled with a neutron conversion structure as discussed above to form a neutron detector chip 400 according to an exemplary embodiment of the present disclosure.

The neutron detector chip 400 can be used in applications that use multiple chips to provide a high neutron detection capability. To support such applications, chip 400 is designed to reduce the number of inputs/outputs (I/O). The amount of interconnect between chips is reduced and the density of chips is increased.

In this example, the architecture of chip 400 includes a plurality 402 of neutron detection circuits (each including a detection latch and a corresponding a charged particle sensor), a 21-bit address generator 404, a counter shift register 406, a serial input 408, a serial output 410, a 5-bit control input 412, and an 8-bit test data output 414. Address generator 404 includes, for example, a Gray counter, which generates addresses for selecting the detection circuits (for “set” or read operations), so no external address lines are required and address switching is minimized. In one example embodiment, only one data input line (Serial Input 408) is used to provide test capability to set or reset the latches. The 8-bit test data output 414 is used during wafer test and, in one embodiment, is not available for package test. Test output 414 can be used to perform a parallel data read at the die level for faster wafer level tests. A single data output (Serial Output 410) is includes serially outputting data, such as when reading the upset count from Upset counter shift register 406. The five input control signals (Control Input 412) are used to control the operation of the neutron detector chip. The chip also includes eight ground pins, four I/O voltage pins, four core voltage pins, and four sense voltage pins, for example. Any other number or type of input and/or output pins can be included in other embodiments.

In an illustrative embodiment, chip 400 includes several million sense elements, detection latches, and corresponding support circuitry, as discussed above. In one example, the chip has two modes of operation, a neutron sense mode and a read mode. In the neutron sense mode, the detector latches (such as those shown in FIGS. 3-5) are placed in a “1” state, and neutron sensing takes place over an extended period of time. In the read mode, the errors are read and counted on the chip by reading the state of each latch on the chip, and then the error count is read out of the chip in a serial mode, for example. An “error” corresponds to a latch that has its state changed from the initial “Set” state. Each of these errors represents the detection of a neutron “hit”. The chip can also be configured to include a test mode in which test circuitry (on or off the chip) sets “1s” in the latches and then reads the “1s” from the latches, for example. The test circuitry then sets “0s” and reads “0s”, for example. This test data is read out of the chip in a parallel mode, for example.

Neutron detection chip 400 can be fabricated to include any number of latches, such as 16 million latches, 32 million latches, or more, depending on the technology. The example shown in FIG. 18 is organized to include 2 million words of 8 latches each, for a total of 16 million neutron detection latches. Each read of the latches on chip 400 has the possibility of having from 0 to 8 upsets in each word. Upset counter shift Register 406 adds the upsets from each read to generate an overall upset count. This upset count is stored in the counter or in another memory element on the chip, for example. At the end of the read operation, or at any other desired time, the error count can be serially read off-chip upon a command provided to the chip through control inputs 412 or under program control on the chip, for example. In one example, the upset counter is capable of counting 16 million upset counts. The upset counter greatly facilitates the use of the neutron detector chip by providing more on-chip analysis capability and simplifying the interface.

The chip interface may be designed to be command driven by a microprocessor, which is connected to the detection chip through the control input. The microprocessor generates a clock and four other control signals that are provided to the detection chip and receives from the chip the upset count and/or the upset data (contents read from the latches) through the Serial Output 410. The low number of signal pins on the neutron detection chip allows a microprocessor to control several chips in parallel.

The microprocessor control also can provide the capability to manage power consumption while the neutron detection chip is in the neutron sense mode. The microprocessor can be programmed to reduce the power supply voltages supplied to the detection chip to lower the standby current and prolong battery life. An added benefit of the voltage control is that it permits control over the sensitivity of the sense element in the neutron sense latch. A reduction of the voltage between the source and drain of the sense element improves the sensitivity of the sense element. An increase of the gate voltage relative to the source voltage reduces the sub-threshold leakage of the sense element.

Such a neutron detector is applicable, for example, in various semiconductor processes, such as but not limited to Silicon-on-Insulator (SOI) processes, for example 90 nm, 65 nm, 45 nm, 32 nm and below SOI processes. Traditional SRAM or Flash memory approaches may not gain efficiency with advancing technology. One or more embodiments of the present disclosure may gain significant efficiency improvements as it is implemented on finer lithography semiconductor processes with an estimated improvement of at least 50% to 75%, for example, with a scaling move from 90 nm to 45 nm technology.

Although the present disclosure has been described with reference to one or more examples, workers skilled in the art will recognize that changes may be made in form and detail without departing from the scope of the disclosure and/or the appended claims.

What is claimed is:

1. A neutron detector device comprising:
a sensing element structure comprising:
a first substrate with a front surface and a back surface, opposite to the front surface; and
a semiconductor sensing element, which is sensitive to a charged particle and is fabricated in an active semiconductor layer on the front surface of the first substrate; and
a neutron conversion structure attached to the back surface and comprising neutron conversion material that emits the charged particle in response to a reaction with neutrons.

2. The neutron detector device of claim 1, wherein:
the neutron conversion structure further comprises a second substrate, distinct from the first substrate, wherein the neutron conversion material is fabricated on the second substrate; and
the neutron conversion structure is attached to the back surface of the first substrate such that the neutron conversion material is positioned between the second substrate and the first substrate.

3. The neutron detector device of claim 1, wherein the device comprises an assembly of the sensing element structure and the neutron conversion structure, which are distinct structures that are adhered together to form the assembly.

4. The neutron detector device of claim 1, wherein the neutron conversion structure is adhered to the sensing element structure by an adhesive positioned between the neutron conversion material and the back surface of the first substrate.

5. The neutron detector device of claim 1, wherein the first substrate has a thickness and comprises:
a cavity extending into the back surface at least partially through the thickness, the cavity overlapping a surface area consumed by the semiconductor sensing element along a plane parallel to the front surface, and wherein the cavity reduces the thickness of the first substrate between the neutron conversion material and the semiconductor sensing element.

6. The neutron detector device of claim 5, wherein the cavity extends through the entire thickness of the first substrate.

7. The neutron detector device of claim 5, wherein:
the first substrate comprises a silicon layer; and
the cavity comprises a gap fill medium having physical properties that attenuate travel of alpha particles and Lithium ions less than the silicon layer.

8. The neutron detector device of claim 7, wherein the gap fill medium is selected from the group consisting of a vacuum, air, helium, hydrogen, nitrogen and neon.

9. The neutron detector of claim 5, wherein the sensing element structure comprises:
a plurality of semiconductor sensing elements, each being fabricated in the active semiconductor layer on the front surface of the first substrate and sensitive to charged particles generated by the neutron conversion material; and
a plurality of cavities extending into the back surface at least partially through the thickness, each of the cavities overlapping a surface area consumed by at least some of the plurality of semiconductor sensing elements along the plane parallel to the front surface.

10. The neutron detector of claim 5, wherein the neutron conversion structure is positioned within the cavity.

11. The neutron conversion structure of claim 10, wherein the cavity and the neutron conversion structure each have a surface area of at least 1 centimeter.

12. The neutron detector device of claim 1, wherein the neutron conversion structure further comprises a second substrate, distinct from the first substrate, and wherein:
the second substrate comprises a front surface facing the back surface of the first substrate;
the front surface of the second substrate comprises a plurality of protrusions or depressions; and
the neutron conversion material is fabricated on the front surface of the second substrate; and
the neutron conversion structure is attached to the back surface of the first substrate such that the neutron conversion material is positioned between the front surface of the second substrate and the back surface of the first substrate.

13. The neutron conversion structure of claim 12, wherein the first substrate has a thickness and wherein the sensing element structure comprises:
a plurality of semiconductor sensing elements, each being fabricated in the active semiconductor layer on the front surface of the first substrate and sensitive to charged particles generated by the neutron conversion material; and
a plurality of cavities extending into the back surface at least partially through the thickness, each of the cavities overlapping a surface area consumed by at least some of the plurality of semiconductor sensing elements along a plane parallel to the front surface, and each of the cavities being aligned with at least one of the plurality of protrusions or depressions.

14. The neutron conversion structure of claim 1, wherein the sensing element structure comprises a neutron detector circuit formed in the active semiconductor layer, wherein the circuit comprises:
the semiconductor sensing element, which comprises a transistor having a body;
a control circuit having a sense mode in which the control circuit is configured to bias the transistor so that the body is electrically-floating and sensitive to the charged particle; and
a latch connected to the control circuit and having a logic state that is controlled by the transistor.

15. A method of manufacturing a neutron detector device, comprising:
fabricating a sensing element structure comprising:
a first substrate with a front surface and a back surface, opposite to the front surface; and
an active semiconductor layer on the front surface of the first substrate, which comprises a semiconductor sensing element that is sensitive to a charged particle; and
fabricating a neutron conversion structure separately from the sensing element structure, the neutron conversion structure comprising neutron conversion material that emits the charged particle in response to a reaction with neutrons; and
attaching the neutron conversion structure to the back surface of the first substrate.

16. The method of claim 15, wherein:
fabricating the neutron conversion structure comprises applying the neutron conversion material to a front surface of a second substrate, distinct from the first substrate; and
attaching comprises attaching the neutron conversion structure to the back surface of the first substrate such that the neutron conversion material is positioned between the second substrate and the first substrate.

17. The method of claim 15, wherein attaching comprises adhering the neutron conversion structure to the sensing element structure by an adhesive positioned between the neutron conversion material and the back surface of the first substrate.

18. The method of claim 15, wherein fabricating the sensing element structure comprises:
forming a cavity in the back surface of the first substrate, which extends at least partially through a thickness of the first substrate, the cavity overlapping a surface area consumed by the semiconductor sensing element along a plane parallel to the front surface, and wherein the cavity reduces the thickness of the first substrate between the neutron conversion material and the semiconductor sensing element when the neutron conversion structure is assembled to the sensing element structure.

19. The method of claim 18, wherein the cavity extends through the entire thickness of the first substrate.

20. The method of claim 18, wherein the first substrate comprises a silicon layer and the method further comprises:
filling the cavity with a gap fill medium during the step of attaching, wherein the gap fill medium has physical properties that attenuate travel of alpha particles and Lithium ions less than the silicon layer.

21. The method of claim 20, wherein the gap fill medium is selected from the group consisting of a vacuum, air, helium, hydrogen, nitrogen and neon.

22. The method of claim 18, wherein the step of attaching comprises positioning the neutron conversion structure within the cavity.

23. The method of claim 22, wherein the cavity and the neutron conversion structure each have a surface area of at least 1 centimeter.

24. The method of claim 15, wherein fabricating the sensing element structure comprises:
fabricating a plurality of semiconductor sensing elements in the active semiconductor layer, each semiconductor sensing element being sensitive to charged particle emitted by the neutron conversion material; and
fabricating a plurality of cavities extending into the back surface at least partially through a thickness of the first substrate, each of the cavities overlapping a surface area consumed by at least some of the plurality of semiconductor sensing elements along the plane parallel to the front surface of the first substrate.

25. The method of claim 15, wherein fabricating the neutron conversion structure further comprises:
fabricating a plurality of protrusions or depressions on a front surface of a second substrate; and
applying the neutron conversion material to the front surface of the second substrate,
wherein attaching comprises attaching the neutron conversion structure to the back surface of the first substrate such that the neutron conversion material is positioned between the second substrate and the first substrate.

26. The method of claim 25, wherein the first substrate has a thickness and wherein:
fabricating the sensing element structure comprises:
fabricating a plurality of semiconductor sensing elements on the active semiconductor layer, each semiconductor sensing element being sensitive to charged particles emitted by the neutron conversion material; and
fabricating a plurality of cavities extending into the back surface at least partially through the thickness, each of the cavities overlapping a surface area consumed by at least some of the plurality of semiconductor sensing elements along a plane parallel to the front surface; and
attaching comprises attaching the neutron conversion structure to the sensing element structure such that each of the cavities is aligned with at least one of the plurality of protrusions or depressions.

27. The method of claim 15, wherein fabricating the sensing element structure comprises:
fabricating a neutron detector circuit in the active semiconductor layer, wherein the circuit comprises:
the semiconductor sensing element, which comprises a transistor having a body;
a control circuit having a sense mode in which the control circuit is configured to bias the transistor so that the body is electrically-floating and sensitive to the charged particle; and
a latch connected to the control circuit and having a logic state that is controlled by the transistor.

28. The method of claim 15, further comprising:
performing a functionality test on at least one of the sensing element structure or the neutron conversion structure subsequent to the steps of fabricating the respective sensing element structure or neutron conversion structure and prior to the step of attaching.

29. A neutron detector comprising:
a sensing element structure comprising a substrate, a semiconductor sensing element that is fabricated on a front surface of the substrate and is sensitive to a charged particle, and a back surface opposite to the first surface;
a neutron conversion structure attached to the back surface, which is configured to generate the charged particle in response to a reaction with a neutron; and
a recess formed in the back surface, between the neutron conversion structure and the semiconductor sensing element.
